(19) United States
(12) Patent Application Publication
(10) Pub. No.: US 2006/0018490 A1
(43) Pub. Date: Jan. 26, 2006

(54) Bessel array

(76) Inventors: Enrique M. Stiles, Imperial Beach, CA (US); Patrick M. Turnmire, Arroyo Seco, NM (US); Richard C. Calderwood, Portland, OR (US)

Correspondence Address: RICHARD C. CALDERWOOD, 2775 NW 126TH AVE, PORTLAND, OR, 97229-8381, US

(21) Appl. No.: 11/220,935

(22) Filed: Sep. 6, 2005

Related U.S. Application Data
(63) Continuation-in-part of application No. 10/896,215, filed on Jul. 20, 2004.

(51) Int. Cl. H04R 1/02; H03G 5/00

(52) U.S. Cl. 381/87; 381/98

(57) ABSTRACT

An improved Bessel array of electromagnetic transducers, in which the Bessel coefficients (phase and/or magnitude) are applied only in the useful high frequency range, where off-axis interference patterns between the outputs of respective transducers cause undesirable acoustic results. One improvement is in using an all-pass filter or the like in lieu of an inverter in the inverting Bessel coefficient path, to provide an in-phase signal in low frequencies and an opposite-phase signal in high frequencies. This achieves the improved off-axis result of a conventional Bessel array, with improved low-frequency maximum sound pressure and efficiency. Another improvement is in using a frequency-dependent voltage divider, such as a shelf circuit, in the half-strength Bessel coefficient paths, to provide full-strength signals in low frequencies and half-strength signals in high frequencies. This achieves even more improved low-frequency maximum sound pressure. Yet another improvement is in using a high-pass filter in front of the inverting Bessel coefficient path, to provide a zero signal in low frequencies and an opposite phase signal in high frequencies.

### RELATED APPLICATION

This application is a continuation-in-part of application Ser. No. 10/896,215 entitled “Single-Sided Bessel Array” filed Jul. 20, 2004 by this inventor and is commonly assigned with it.

### BACKGROUND OF THE INVENTION

1. Technical Field of the Invention

This invention relates generally to transducers such as audio speakers, and more specifically to an array of transducers which operate as a Bessel array in higher frequencies and as a conventional array in lower frequencies.

2. Background Art

It is well known to organize two or more transducers together into a variety of array configurations. One popular configuration is the line array.

FIG. 1 illustrates a conventional line array system 10. A plurality of transducers 12 are arranged in a linear fashion. In some instances, the transducers may be substantially identical. Although five transducers are shown, line arrays may use any number of transducers. Commonly, the transducers are coupled to a single, common enclosure 14. The transducers are driven in phase by a common signal (as indicated by the “+1” indication at the input to each transducer) from an amplifier 16.

As compared to a single transducer, a line array composed of multiple units of that same transducer offers the advantage of increased maximum sound pressure (sometimes referred to as loudness or volume), due simply to there being more transducers moving air, and also offers the advantage of higher efficiency, due to mutual air coupling between the transducers leading to improved impedance matching. However, line arrays can suffer from undesirable effects, such as interference patterns, which are observed at off-axis listening positions. In this context, “off-axis” refers to positions which are removed in a direction parallel to the “line” of the line array; for example, in FIG. 1 the off-axis positions are up and down, rather than left and right of the line array. These effects result, in large measure, from the listener being at slightly different distances from each of the respective transducers, and sound from the closer transducers arriving sooner than sound from the farther transducers. The farther off-axis the listener moves, the greater the differences between the listener and each of the transducers. At various off-axis positions, some frequencies will be subject to constructive interference while other frequencies will be subject to destructive interference. At other off-axis positions, different sets of frequencies will be subject to constructive or destructive interference. In general, because high frequencies have shorter wavelengths than low frequencies, these off-axis effects are more pronounced in the higher frequencies and begin to significantly occur when the frequency is sufficiently high such that its wavelength is only twice as long as the spacing between adjacent transducers in the array. At this frequency, the output of two adjacent transducers will completely cancel each other out at an angle of 90 degrees off-axis, because the output of one will be exactly 180 degrees out of phase with the output of the other.

FIG. 2 is a graph that illustrates the performance of one example of a line array, with five transducers on 4 cm center-to-center spacing. The horizontal (X) axis is frequency, and the vertical (Y) axis is sound pressure. Sixteen response curves are plotted; the on-axis curve is shown as a solid line, and the dotted lines represent fifteen response curves measured at 2 degree increments off-axis. The line array exhibits very good performance, with 98 dB sound pressure and minimal interference effects below about 1 kHz. Above about 1 kHz, however, the line array begins to exhibit significant comb filter interference patterns.

U.S. Pat. No. 4,399,328 to Franssen teaches the known but little-used Bessell array of speakers, which was designed to address exactly this problem. Its principles will be explained with reference to FIGS. 2-4.

FIG. 3 illustrates a Bessel array 20 of transducers 12 coupled to an enclosure 14 and driven by an amplifier 16. Rather than simply being provided directly to each transducer, as in a line array, the audio signal from the amplifier is altered to be suitable for the Bessel array by a circuit 22. The amplifier may be a pre-amplifier, and the final power amplification may be performed between the Bessel circuit and the transducers through the use of multiple power amplifiers.

The advantage offered by a Bessel array is control of constructive and destructive interference patterns in listening positions which are off-axis in the direction of the line array—vertically in the example of FIG. 3. A Bessel array reduces this effect by powering the various speaker drivers with differently conditioned signals, rather than by merely splitting the same signal equally five ways. In the common five-driver Bessel array, the first driver 12-1 receives a half-strength, in-phase signal (referred to as “+½”); the second driver 12-2 receives a full-strength, inverted-phase signal (referred to as “−1”); the third and fourth drivers 12-3 and 12-4 each receives a full-strength, in-phase signal (“+1”); and the fifth driver 12-5 receives a half-strength, in-phase signal (“+½”).

One method of providing the “−1” signal is simply to reverse the connections at the + and − terminals of the second driver. One method of providing the “+½” signals is to connect the first and fifth drivers in series with each other, and that series combination in parallel with each of the other drivers, as taught by Franssen. In other embodiments, the Bessel circuit may be e.g. a digital logic device.

In some embodiments, a single amplifier's output is used to drive all of the transducers in the Bessel array. In other embodiments, each transducer may be driven by its own, dedicated amplifier; in such embodiments, each amplifier's output may be adjusted such that its output corresponds to the required Bessel coefficient for that particular driver. In that case, the amplifier settings themselves function as the Bessel circuit.

A Bessel array sacrifices maximum sound pressure and efficiency versus a line array configuration of the same drivers, to gain improved off-axis sound performance. In low frequencies, a five-driver Bessel array uses five speaker drivers to generate the same sound pressure level that would be generated by two speaker drivers in a conventional line array.

FIG. 4 is a graph illustrating the frequency response of a conventional 5-driver Bessel array with 4 cm center-to-center spacing, in 2 degree increments from 30 degrees below to 30 degrees above center. Comparing FIG. 4 to FIG. 2, it is readily seen that the Bessel array has significantly reduced off-axis interference patterns compared to the conventional line array. However, it is also readily seen that the Bessel array has significantly reduced sound pressure than the conventional line array using the same transducers, the same amplifier (although only being driven at ⅘ths relative output), and the same signal—the conventional line array offers roughly 98 dB on-axis, while the Bessel array offers only 90 dB, an 8 dB reduction in the sound pressure level.

Furthermore, it is also seen that the conventional Bessel array performs the same interference pattern reduction, and loss of sound pressure, across the entire frequency range, whereas the interference pattern is really only a problem in the higher frequencies. At lower frequencies, the wavelengths are sufficiently long to swamp the distance difference between the off-axis listener and the respective speaker drivers.

Franssen teaches Bessel arrays having five, seven, or nine driver positions, which may be referred to as 5-Order, 7-Order, and 9-Order Bessel Arrays. Franssen teaches driving these arrays with the following signals (after converting from Franssen's terminology to Applicant's):

| Driver | 5-Order Signal | 7-Order Signal | 9-Order Signal |
|---|---|---|---|
| 1 | +½ | +½ | +½ |
| 2 | +1 | +1 | +1 |
| 3 | +1 | +1 | +1 |
| 4 | −1 | 0 | 0 |
| 5 | +½ | −1 | −1 |
| 6 | n/a | +1 | 0 |
| 7 | n/a | −½ | +1 |
| 8 | n/a | n/a | −1 |
| 9 | n/a | n/a | +½ |

What is desirable, then, is a Bessel array which performs its interference pattern reduction function more in higher frequencies than in lower frequencies and which has more overall sound pressure and efficiency than a conventional Bessel array.

### BRIEF DESCRIPTION OF THE DRAWINGS

FIG. 1 shows a line array according to the prior art.

FIG. 2 is a graph showing the frequency response of the 5-driver line array of FIG. 1.

FIG. 3 shows a 5-Order Bessel Array according to the prior art.

FIG. 4 is a graph showing the frequency response of the conventional 5-Order Bessel Array of FIG. 3.

FIG. 5 shows an Improved 5-Order Bessel Array according to one embodiment of this invention.

FIGS. 6A and 6B are graphs showing the frequency response of the Improved 5-Order Bessel array of FIG. 5.

FIG. 7 shows a 5×5-Order Bessel Square Array according to the prior art.

FIG. 8 shows an Improved 5×5-Order Bessel Square Array according to another embodiment of this invention.

FIG. 9 shows another embodiment of an Improved 5-Order Bessel Square Array with the frequency-dependent Bessel coefficient feature applied in both row and column circuitry.

FIG. 10 shows yet another embodiment of an Improved 5×5-Order Bessel Square Array.

FIG. 11 shows another embodiment of an Improved 5-Order Bessel Array with an additional improvement in that both the inverted Bessel coefficient and the half-amplitude Bessel coefficients are provided in a frequency dependent manner.

FIG. 12 shows a 7-Order Bessel Array according to the prior art.

FIG. 13 shows an Improved 7-Order Bessel Array according to another embodiment of this invention.

FIG. 14 shows a 9-Order Bessel Array according to the prior art.

FIG. 15 shows an Improved 9-Order Bessel Array according to another embodiment of this invention.

FIG. 16 shows an Improved 7×7 Bessel Square Array according to another embodiment of this invention.

FIGS. 17-18 show various Improved 7-Order Bessel Arrays according to other embodiments of this invention.

FIG. 19 shows a 7-Order Bessel Array used as the woofer section of a 2-way speaker system.

FIG. 20 shows an Improved 7-Order Bessel Array used as the woofer section of a 2-way speaker system.

FIG. 21 shows an another Improved 5-Order Bessel Array according to another embodiment of this invention, used as the woofer section of a 2-way speaker system.

FIG. 22 shows an another Improved 9-Order Bessel Array according to another embodiment of this invention, used as the woofer section of a 2-way speaker system.

FIG. 23 shows a frequency response simulation graph of a modeled full range transducer. This reference transducer is used as the basis for modeling the systems of FIGS. 24-36.

FIG. 24 shows a conventional 5-driver line array using the reference transducer whose frequency response is given in FIG. 23, and FIGS. 24UP and 24DOWN are frequency response simulation graphs of frequency response measured in 10-degree increments from 0° to +40° off-axis, and 0° to −40° off-axis, respectively. Subsequent FIGxxUP and FIGxxDOWN charts are similarly constructed.

FIG. 25 shows a conventional 5-driver Bessel array, and FIGS. 25UP and 25DOWN are its frequency response simulation graphs.

FIG. 26 shows another conventional 5-driver Bessel array, and FIGS. 26UP and 26DOWN are its frequency response simulation graphs.

FIG. 27 shows a 5-driver Bessel array enhanced with a 1^{st} order high-pass filter, and FIGS. 27UP and 27DOWN are its frequency response simulation graphs.

FIG. 28 shows a 5-driver Bessel array enhanced with a 2^{nd} order high-pass filter, and FIGS. 28UP and 28DOWN are its frequency response simulation graphs.

FIG. 29 shows of a 5-driver Bessel array enhanced with a shelf circuit, and FIGS. 29UP and 29DOWN are its frequency response simulation graphs.

FIG. 30 shows a 5-driver Bessel array enhanced with a different shelf circuit, and FIGS. 30UP and 30DOWN are its frequency response simulation graphs.

FIG. 31 shows a 5-driver Bessel array enhanced with an all-pass filter, and FIGS. 31UP and 31DOWN are its frequency response simulation graphs.

FIG. 32 shows a 5-driver Bessel array enhanced with both a shelf circuit and an all-pass filter, and FIGS. 32UP and 32DOWN are its frequency response simulation graphs.

FIG. 33 shows a frequency response graph of a transducer whose output is biased toward the high frequencies, such as a horn loaded driver, or a driver with an extremely powerful motor and a very light moving mass. FIGS. 33UP and 33DOWN are frequency response simulation graphs for a 5-driver Improved Bessel Array using the high frequency biased driver rather than the full range driver of FIG. 23.

FIG. 34 shows a conventional 4-driver line array, and FIGS. 34UP and 34DOWN are its frequency response simulation graphs. FIGS. 34 to 37 use the full range transducer of FIG. 23, not the horn loaded driver of FIG. 33.

FIG. 35 shows a 4-driver Reduced-Bessel Array, and FIGS. 35UP and 35DOWN are its frequency response simulation graphs.

FIG. 36 shows a 4-driver Reduced Bessel Array, and FIGS. 36UP and 36DOWN are its frequency response simulation graphs.

FIG. 37 shows a comparison of the UP sides of the output of the Reduced Bessel Arrays of FIGS. 34 and 35.

FIG. 38 shows an Improved 4-driver Reduced Bessel Array, and FIGS. 38UP and 38DOWN are its frequency response simulation graphs.

FIG. 39 shows another Improved 4-driver Reduced Bessel Array, and FIGS. 39UP and 39DOWN are its frequency response simulation graphs.

FIG. 40 shows another Improved 4-driver Reduced Bessel Array, and FIGS. 40UP and 40DOWN are its frequency response simulation graphs.

FIG. 41 shows an Improved 9-Order Bessel Array in which the amplifiers are located between the Bessel circuit and the transducers.

FIG. 42 shows an Improved 5-Order Bessel Array using dual-voice-coil transducers.

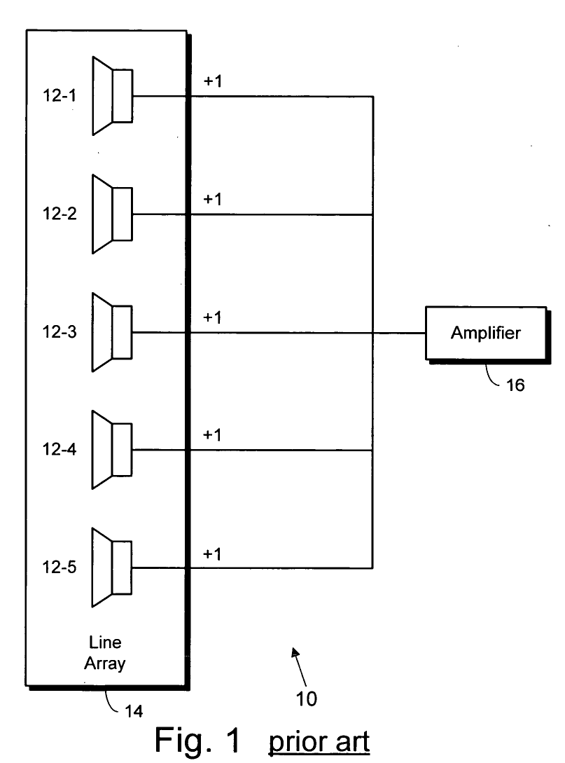

### DETAILED DESCRIPTION

The invention will be understood more fully from the detailed description given below and from the accompanying drawings of embodiments of the invention which, however, should not be taken to limit the invention to the specific embodiments described, but are for explanation and understanding only.

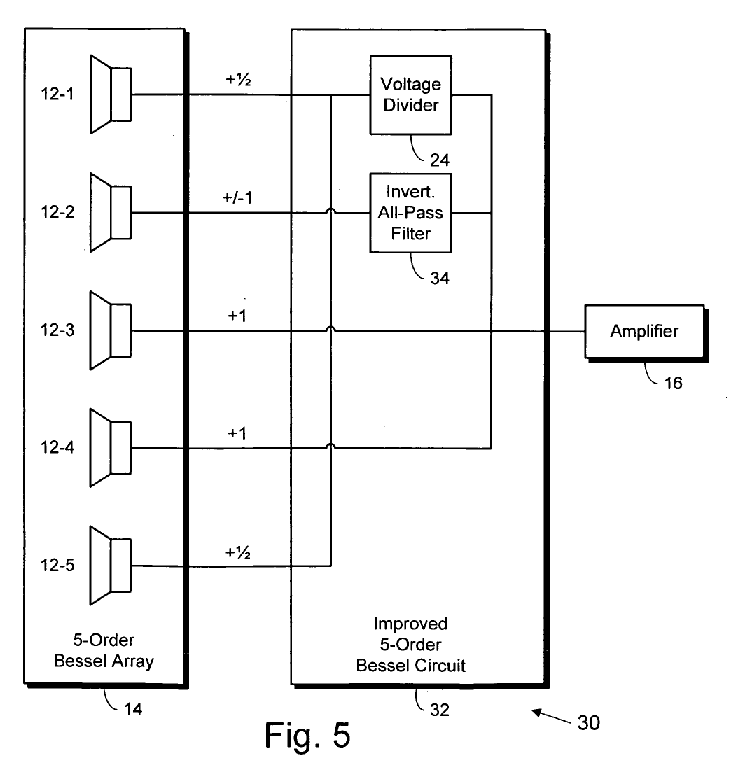

FIG. 5 illustrates one embodiment of an Improved 5-Order Bessel Array 30 according to this invention. The Bessel array may use a conventionally configured array of speaker drivers 12-1 to 12-5 mounted in an enclosure 14 and powered by a conventional source such as an amplifier 16.

The improvement lies in the Bessel circuit 32 which conditions the amplifier output to apply the required Bessel coefficients to the signals supplied to each of the respective drivers. In the five-driver Bessel array shown, the first driver 12-1 and fifth driver 12-5 each receives an in-phase, half-strength (“+½”) signal whose strength is reduced by a conventional voltage divider 24 or other suitable means (such as being coupled in series); the second driver 12-2 receives its signal (“+/−1”) from an inverting all-pass filter 34 or other such circuit which performs the desired function; and the third driver 12-3 and fourth driver 12-4 each receives a simple pass-through of the amplifier signal (“+1”).

The inverting all-pass filter inverts the phase of high-frequency signals, but does not invert the phase of low-frequency signals; thus, the signal is identified as “+/−1” suggesting that it is “+1” in lower frequencies and “−1” in higher frequencies. The designer can select the phase-inverting cross-over point to be at any frequency, based on driver spacing and desired off-axis response control.

Thus, the improved Bessel array is a “single-sided” Bessel array, in that it behaves like a Bessel array on one side (the high-frequency side) of its frequency range, but more like a conventional line array on the other side (the low-frequency side). It may also be thought of as being single-sided in that, in some embodiments, it will exhibit better performance in one off-axis direction than in the other.

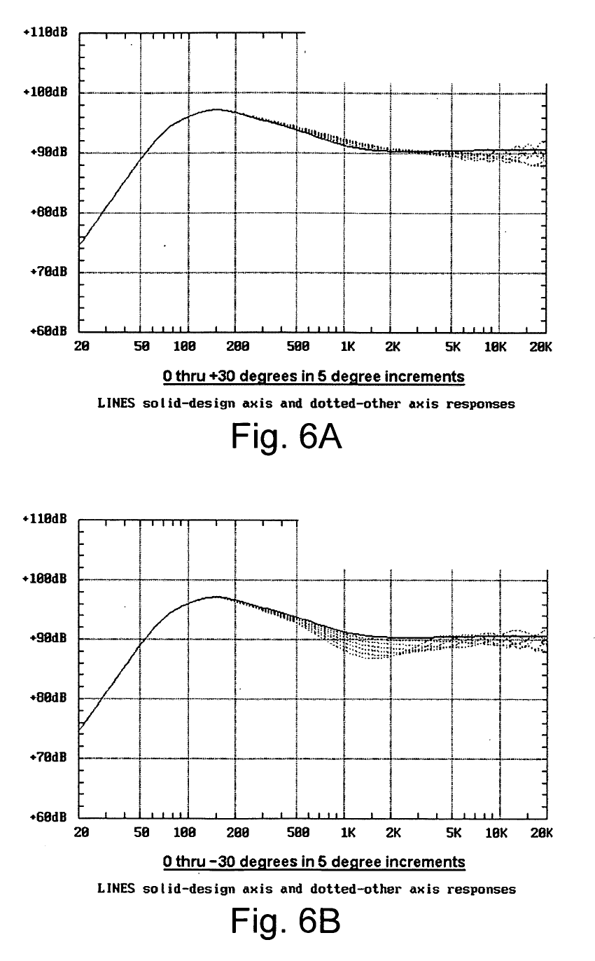

FIGS. 6A and 6B are graphs illustrating the off-axis performance of the improved Bessel array of FIG. 5, which has 5 drivers on 4 cm center-to-center spacing. FIGS. 6A and 6B show the performance from center to 30 degrees above and below center, respectively, in 5 degree increments.

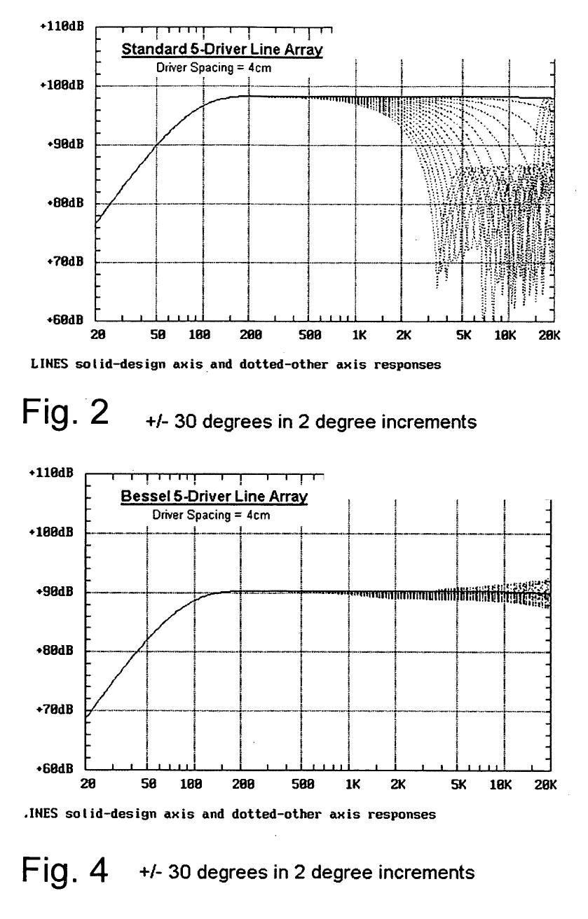

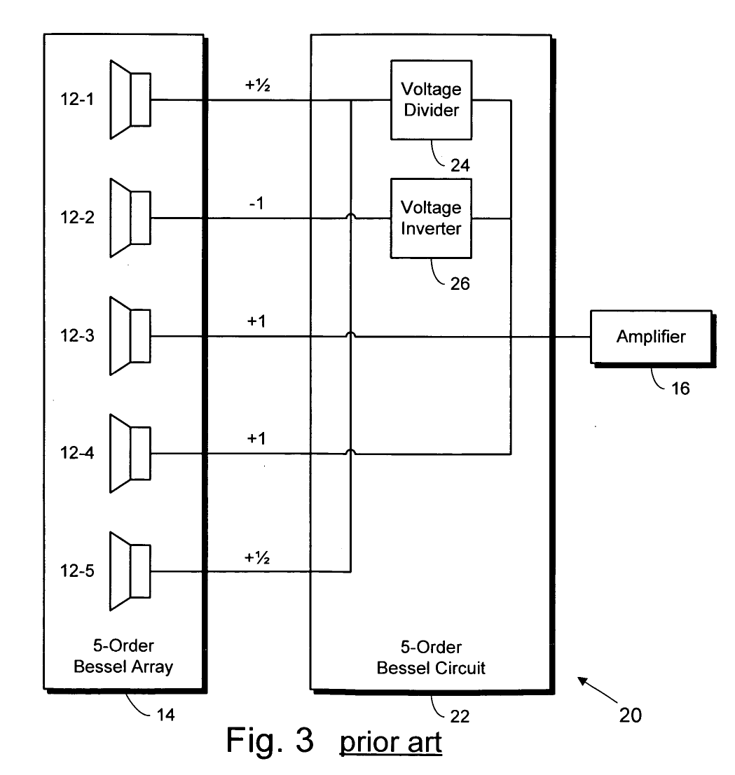

Comparing FIGS. 6, 4, and 2, it is seen that in the lower frequencies, the sound pressure level of the improved Bessel array of this invention is significantly better than that of the conventional Bessel array, and in the higher frequencies, the interference exhibited by the improved Bessel array of this invention is significantly better than that of a conventional line array and nearly as good as the conventional Bessel array. The improved Bessel array is somewhat asymmetrical, as seen by comparing FIG. 6A to FIG. 6B, in that it has a different amount of off-axis interference control in one off-axis direction than in the other.

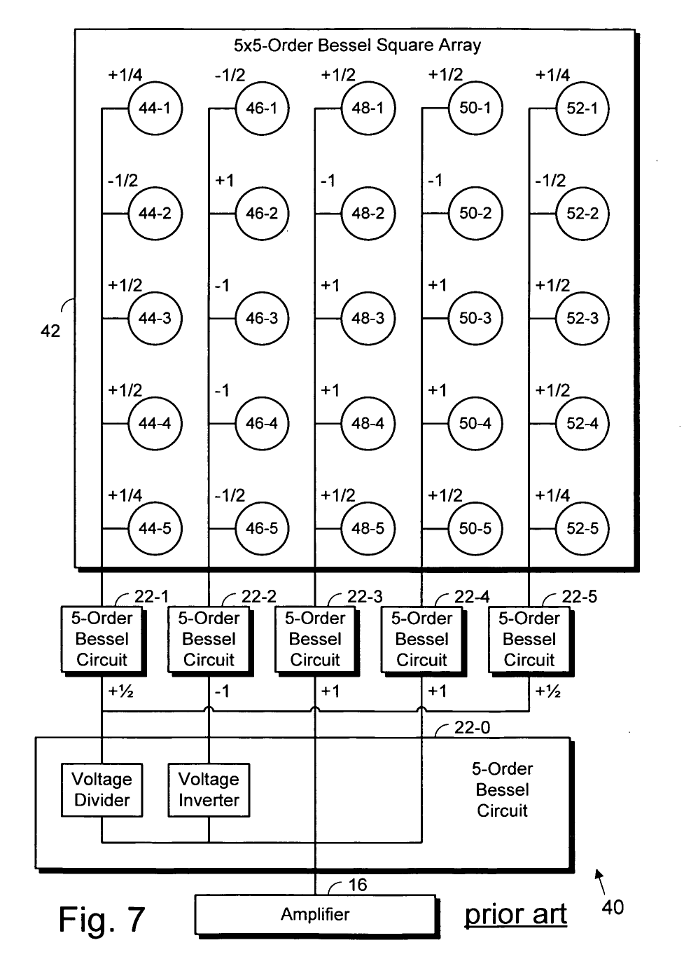

FIG. 7 illustrates a Bessel square array 40 according to the prior art, including an array of speaker drivers coupled to an enclosure 42. The Bessel square array is a “Bessel of Bessels”. The speaker drivers are arranged in a two-dimensional array, typically but not necessarily having equal numbers of rows and columns. The speaker drivers within each given column are driven in Bessel array fashion, and the columns themselves are driven in Bessel array fashion.

The amplifier output is provided to a main Bessel circuit 22-0. Each output of the main Bessel circuit is provided as an input to a respective secondary or column Bessel circuit 22-1 through 22-5. Each of the secondary Bessel circuits drives a corresponding Bessel array of drivers arranged in a column. The first column Bessel circuit 22-1 drives a first Bessel array of drivers 44, the second column Bessel circuit 22-2 drives a second Bessel array of drivers 46, and so forth. Each secondary Bessel circuit applies the Bessel function to whatever input signal it receives from its respective output of the main Bessel circuit. Thus, the signal provided to any given speaker driver is the product of its main and column Bessel signal values.

The five drivers 44 in the first column are driven in Bessel array fashion, with the first driver 44-1 and the fifth driver 44-5 each receives a quarter-strength, in-phase signal “+¼”; the second driver 44-2 receives a half-strength, opposite-phase signal “−½”; and the third driver 44-3 and the fourth driver 44-4 each receives a half-strength, in-phase signal “+½”. The five drivers 52 in the fifth column are driven the same as those in the first column.

The five drivers 46 in the second column are driven collectively by the “−1” of the main Bessel, which is fed through the second column Bessel circuit 22-2. The first driver 46-1 and the fifth driver 46-5 each receives a half-strength, opposite-phase signal “−½”; the second driver 46-2 receives a full-strength, in-phase signal “+1” (a double negative); and the third driver 46-3 and the fourth driver 46-4 each receives a full-strength, opposite-phase signal “−1”.

The third column Bessel circuit 22-3 receives a “+1” signal from the main Bessel circuit. The first driver 48-1 and the fifth driver 48-5 each receives a half-strength, in-phase signal “+½”; the second driver 48-2 receives a full-strength, opposite-phase signal “−1”; and the third driver 48-3 and the fourth driver 48-4 each receives a full-strength, in-phase signal “+1”. The five drivers 50 in the fourth column are driven the same as those in the third column.

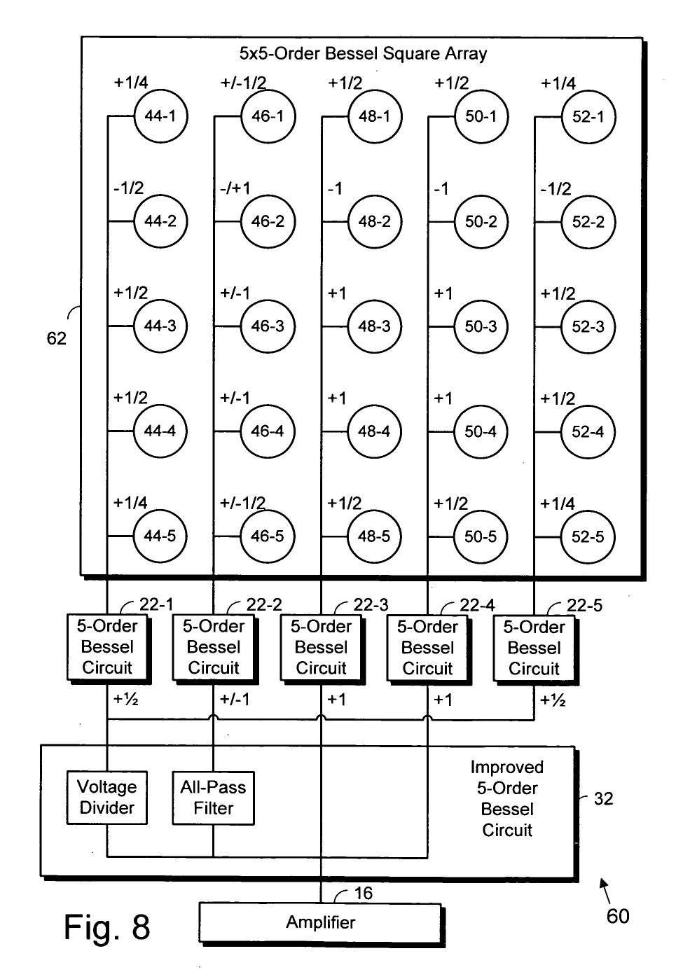

FIG. 8 illustrates the improved Bessel square array 60 according to one embodiment of this invention. In the embodiment shown, the inverting all-pass filter improvement is applied to only the primary Bessel circuit, with the five column Bessel circuits being conventional Bessel circuits which simply invert the phase of their input signals to generate their second drivers' respective signals

The first, third, fourth, and fifth columns' drivers receive the same signals as in the conventional Bessel square array of FIG. 7. The improvement lies in the signals applied to the second column—the position which, in a conventional Bessel array receives the “−1” signal but which, in this invention such as shown in FIG. 5, receives the “+/−1” signal.

The operation of the second column is slightly more complex than in the conventional Bessel square array, because according to this invention it receives a single-sided all-pass filter phase shifted signal “+/−1” from the second output of the primary Bessel circuit.

In the low frequencies, the primary Bessel circuit is outputting a “+1” signal at its second output, and the second column Bessel circuit 22-2 provides a “+½” signal (main “+1” times column “+½”) to the first driver 46-1 and to the fifth driver 46-5; a “−1” (main “+1” times column “−1”) signal to the second driver 46-2; and a “+1” (main “+1” times column “+1”) signal to each of the third driver 46-3 and the fourth driver 46-4.

In the high frequencies, the primary Bessel circuit is outputting a “−1” signal at its second output, and the second column Bessel circuit 22-2 provides a “− 1/2” signal (main “−1” times column “+½”) to the first driver 46-1 and to the fifth driver 46-5; a “+1” (main “−1” times column “−1”) signal to the second driver 46-2; and a “−1” (main “−1” times column “+1”) signal to each of the third driver 46-3 and the fourth driver 46-4.

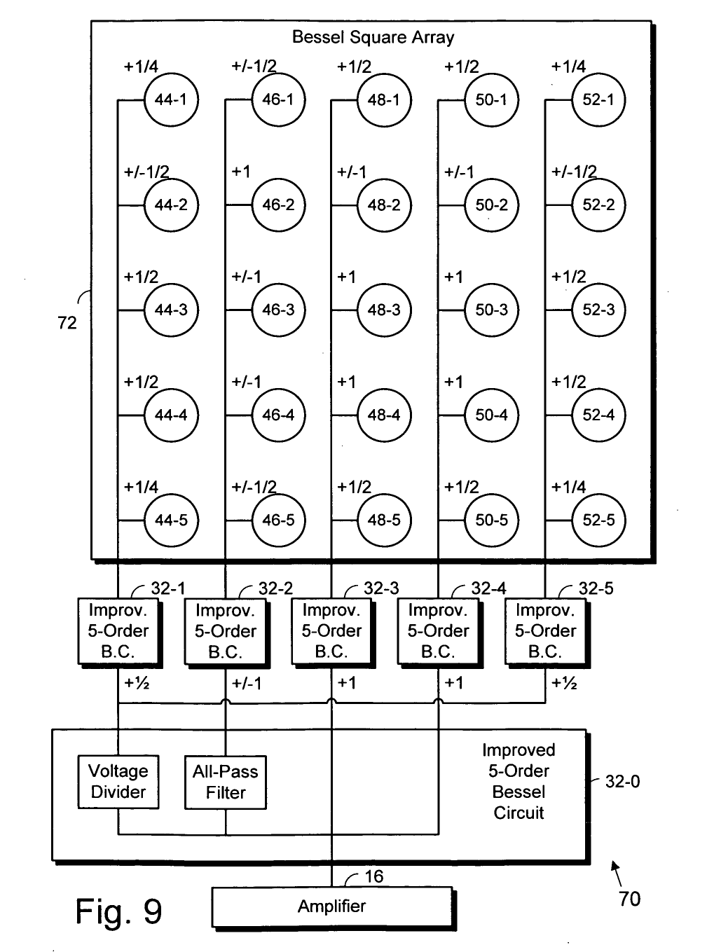

FIG. 9 illustrates another embodiment of an improved Bessel square array 70 in which the improved Bessel circuit is used in both the main (row) Bessel and the column Bessel functions. The output from the amplifier(s) is fed into an improved main Bessel circuit 32-0. The outputs of the main Bessel circuit are fed into respective improved column Bessel circuits 32-1 through 32-5.

The advantage gained over the embodiment of FIG. 8 lies in the second row of transducers. In the low frequencies, each of those five drivers 44-2, 46-2, 48-2, 50-2, and 52-2 receives an in-phase “+” signal, whereas in FIG. 8 each received an opposite phase “−” signal in the low frequencies. In the FIG. 8 configuration, the second row transducers contribute to low frequency sound pressure, rather than diminishing it. The disadvantage is that there are now six instances of the inverting all-pass filter circuitry—one in the main Bessel circuit, and five in the respective column Bessel circuits.

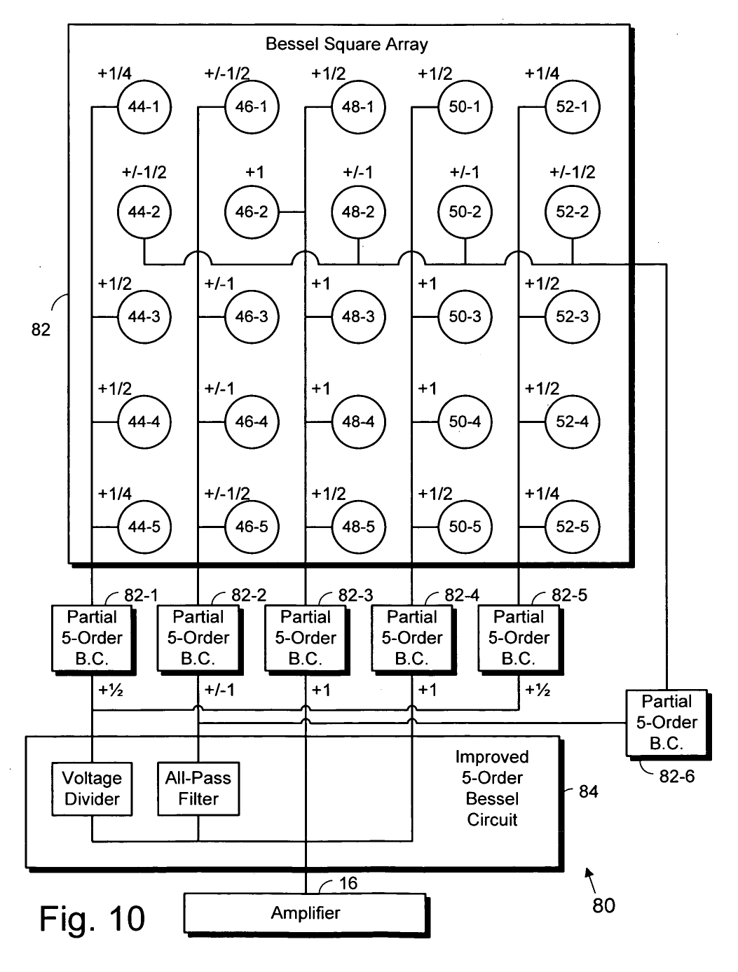

FIG. 10 illustrates another embodiment of a Bessel square array 80 which retains the low frequency performance advantage of FIG. 9, but which requires only a single inverting all-pass filter circuit. The amplifier output is provided to an improved main Bessel circuit 84. The five Bessel coefficient outputs of the main Bessel circuit are fed into five respective column partial Bessel circuits 82-1 through 82-5. These are partial Bessel circuits in that they lack the inverting (second) Bessel output. A sixth partial Bessel circuit 82-6 is driven, in parallel with the second column partial Bessel circuit 82-2, with the frequency-dependent inverting output of the main Bessel circuit. This sixth partial Bessel circuit drives transducers 44-2, 48-2, 50-2, and 52-2 as indicated. The transducer 44-2 which lies at the missing inverting output of both the second column partial Bessel circuit 82-2 and the sixth partial Bessel circuit 82-6 is driven with a “+1” signal, which may be supplied by any handy source such as any other “+1” output or by its own amplifier or what have you.

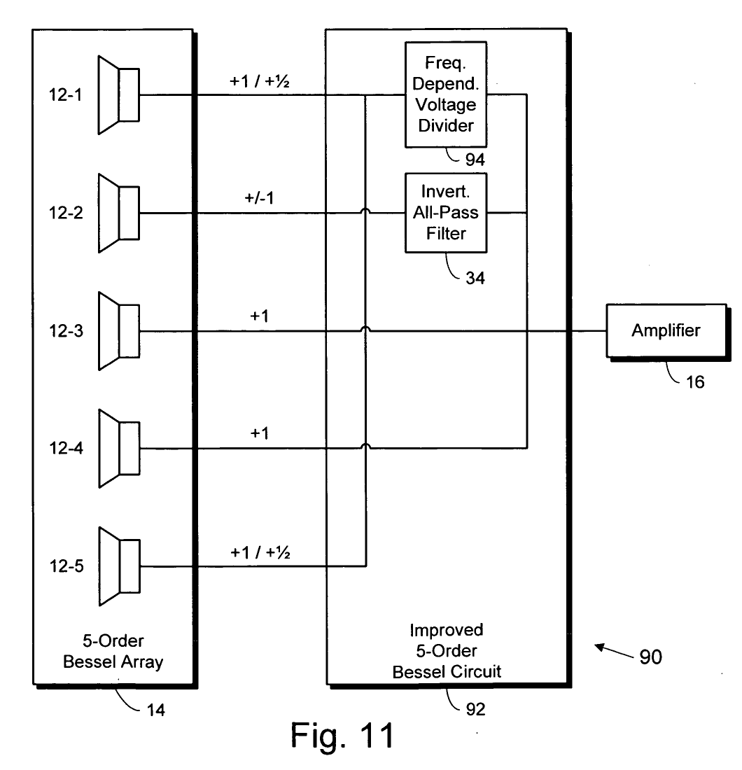

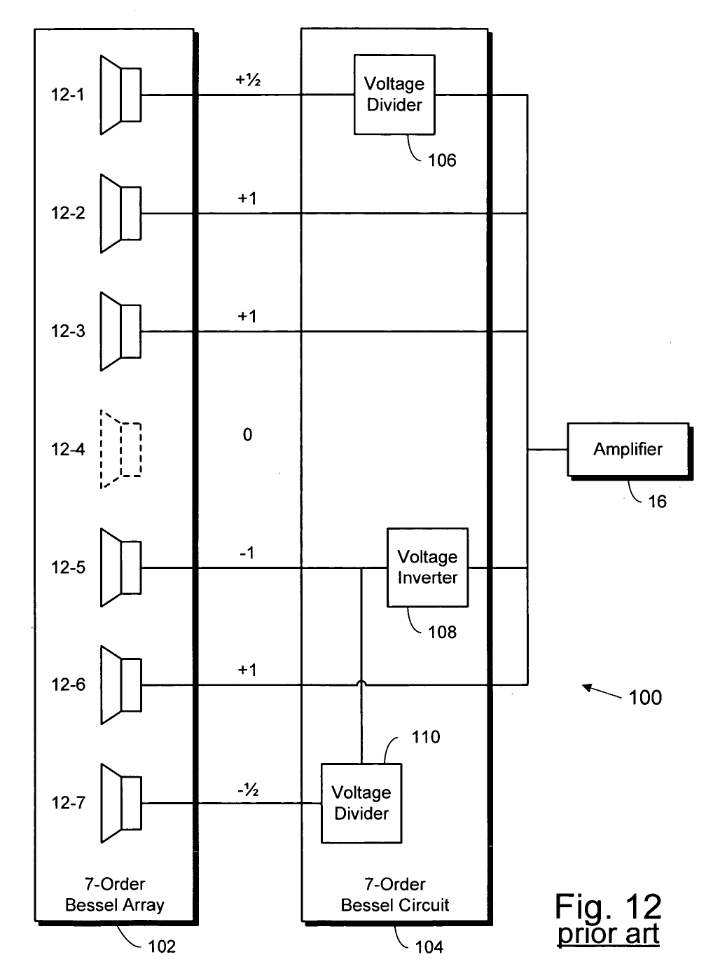

FIG. 11 illustrates the frequency-dependent improvement applied not only to the inverting (second) Bessel signal but also to the half-strength (first and fifth) Bessel signals, as well. The improved Bessel system 90 includes an improved Bessel circuit 92, which includes the inverting all-pass filter 34 providing its second output and the straight pass-through paths providing its third and fourth outputs. In place of a conventional voltage divider (or series connection) at its first and fifth outputs, it includes a frequency-dependent voltage divider 94 providing its first and fifth outputs.

In low frequencies, the frequency-dependent voltage divider does not perform any significant voltage division, and the first and fifth transducers receive full-strength, in-phase “+1” signals; the inverting all-pass filter does not perform phase inversion, and the second transducer receives a full-strength, in-phase “+1” signal; and, as always, the third and fourth transducers receive full-strength, in-phase “+1” signals. Thus, in low frequencies, the improved Bessel array performs substantially like a conventional line array, offering maximum sound pressure and efficiency.

In high frequencies, the frequency-dependent voltage divider performs voltage division, such that the first and fifth transducers receive half-strength, in-phase “+½” signals; the inverting all-pass filter provides a full-strength, opposite-phase “−1” signal to the second transducer; and the third and fourth transducers continue to receive full-strength, in-phase “+1” signals. Thus, in high frequencies, the improved Bessel array performs substantially like a conventional Bessel array, reducing interference patterns in off-axis listening positions.

This frequency-dependent voltage divider improvement can, of course, be applied to a Bessel square array, as well.

FIG. 12 illustrates a 7-Order Bessel Array 100 according to the prior art, including an array of transducers 12-1 through 12-3, and 12-5 through 12-7 coupled to an enclosure 102 on equal on-center vertical spacing. The transducers are powered by a Bessel circuit 104 which receives an input signal from an amplifier 16. The Bessel circuit includes a voltage divider 106 which drives the first transducer 12-1 with an in-phase, half-amplitude “+½” signal. Second and third transducers 12-2 and 12-3 are driven by in-phase, full-amplitude “+1” signal directly from the amplifier. The fourth transducer 12-4 is driven with a null signal “0” and, consequently, is omitted from the array. The Bessel circuit further includes a first voltage inverter 108 drives a fifth transducer 12-5 with an opposite-phase, full-amplitude “−1” signal, which can also be accomplished by simply connecting the wires to the transducers in reverse polarity. The distance between the fifth transducer and the third transducer is twice the distance between other transducers, because although the fourth transducer (12-4) is not present, its position is used in maintaining the correct spacing for the Bessel array to function correctly. A sixth transducer 12-6 is driven by an in-phase, full-amplitude “+1” signal. The Bessel circuit includes a second voltage divider 110 which receives the opposite-phase signal from the voltage inverter, and drives a seventh transducer 12-7 with an opposite-phase, half-amplitude “−½” signal.

This conventional 7-Order Bessel Array uses six transducers but produces only two transducers' worth of sound pressure level. The first and seventh transducers cancel each other, and the fifth and sixth transducers cancel each other.

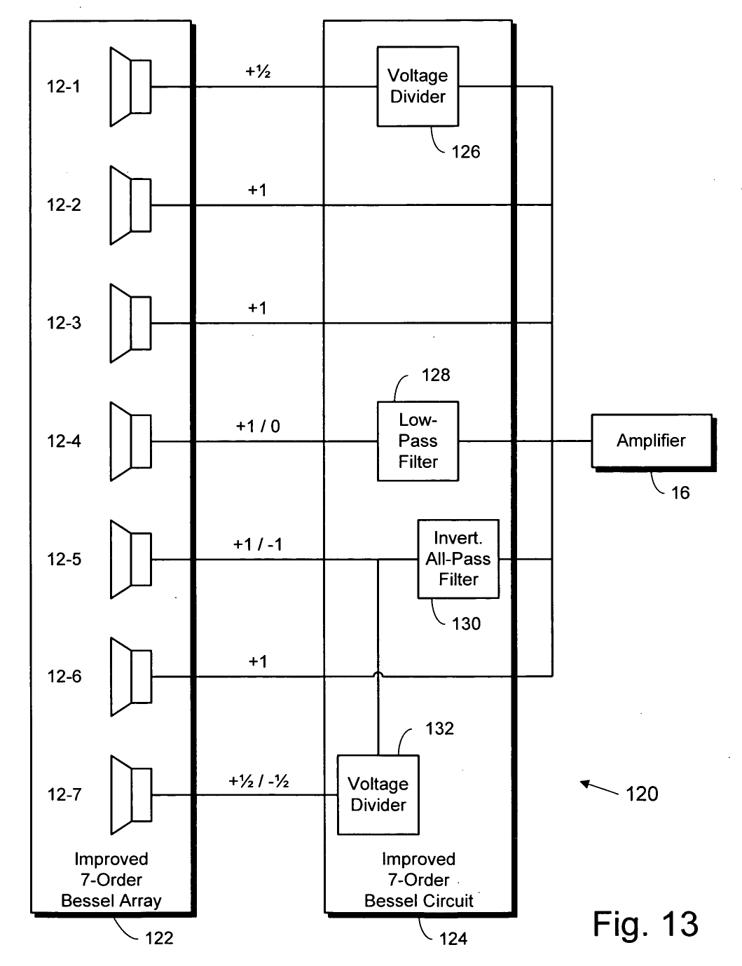

FIG. 13 illustrates an Improved 7-Order Bessel Array 120 according to another embodiment of this invention. Seven transducers 12-1 through 12-7 are coupled to an enclosure 122, as compared to only six transducers in the prior art system. An Improved 7-Order Bessel Circuit 124 includes a first voltage divider 126 coupled to drive the first transducer 12-1 with an in-phase, half-amplitude “+½” signal. The second, third, and sixth transducers 12-2, 12-3, and 12-6 are coupled to be driven with an in-phase, full-amplitude “+1” signal from the amplifier 16. The circuit includes an inverting all-pass filter 130 which is coupled to drive the fifth 12-5 transducer with a full-amplitude “+/−1” signal which is in-phase in a low frequency range and opposite-phase in a high frequency range. A second voltage divider 132 also receives the output of the inverting all-pass filter and drives the seventh transducer 12-7 with a half-amplitude “+/−½” signal which is in-phase in a low frequency range and opposite-phase in a high frequency range. To this point, it is similar to the Improved 5-Order Bessel Arrays described above.

However, the 7-Order Bessel differs from the 5-Order Bessel in that it includes a “0” signal. In this configuration, the circuit includes a low-pass filter 128 coupled to drive the fourth transducer 12-4 with a signal which is in-phase, full-amplitude “+1” in a low frequency range, and a substantially null “0” in a high frequency range.

This improved 7-Order Bessel uses seven transducers and produces six transducers' worth of sound pressure in a low frequency range, and two transducers' worth of sound pressure in a high frequency range. If the voltage dividers were replaced by frequency-dependent voltage dividers, it would produce seven transducers' worth of sound pressure in the low frequency range.

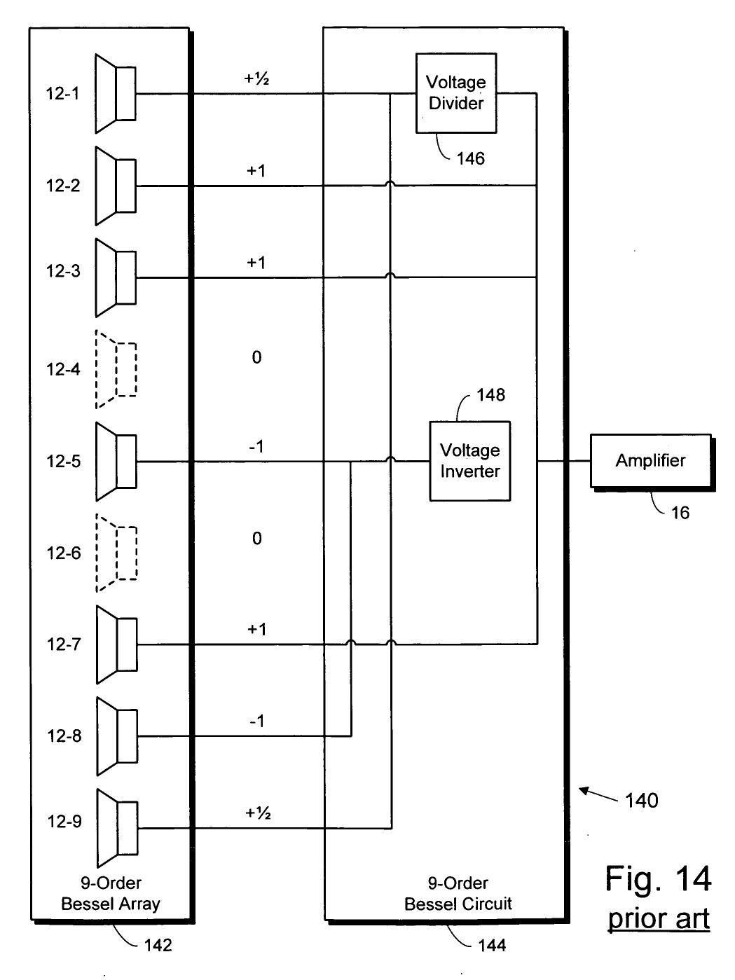

FIG. 14 illustrates a 9-Order Bessel Array 140 according to the prior art. Seven transducers 12-1 through 12-3, 12-5, and 12-7 through 12-9 are coupled to an enclosure 142, with two positions (12-4 and 12-6) being unoccupied. The transducers are driven by a 9-Order Bessel Circuit 144 which receives a signal from an amplifier 16. A voltage divider 146 provides an in-phase, half-amplitude “+½” signal to the first and ninth transducers 12-1 and 12-9. The second, third, and seventh transducers 12-2, 12-3, and 12-7 are driven by in-phase, full-amplitude “+1” signals directly from the amplifier. A voltage inverter 148 provides an opposite-phase, full-amplitude “−1” signal to the fifth and eighth transducers 12-5 and 12-8.

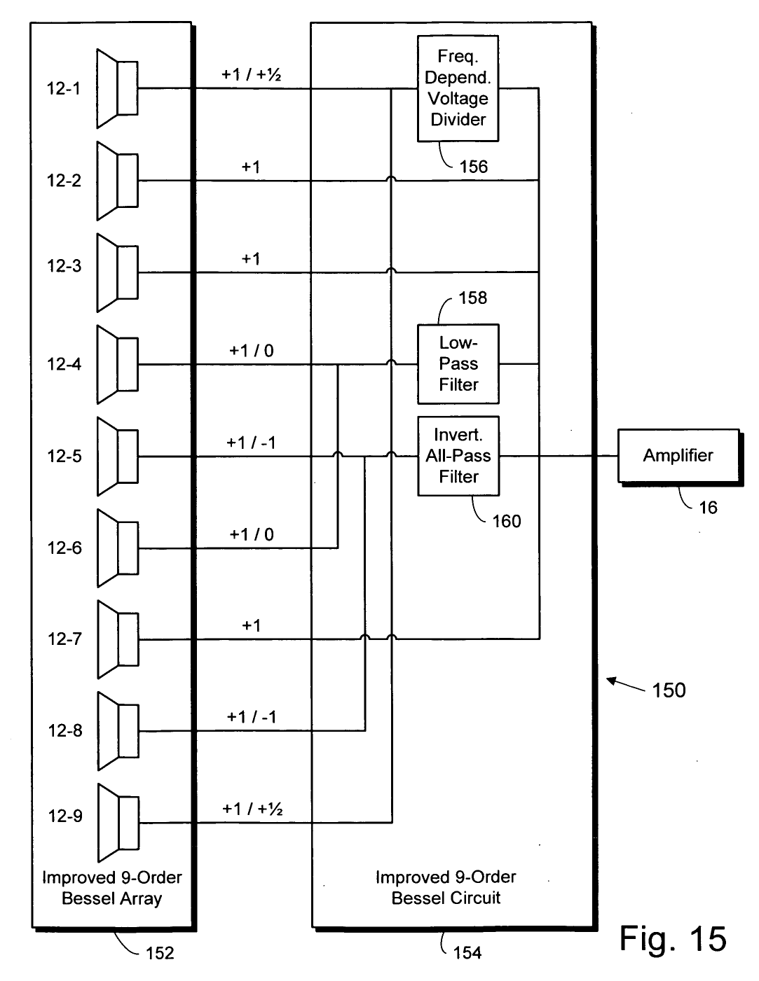

FIG. 15 illustrates an Improved 9-Order Bessel Array 150 according to another embodiment of this invention. Nine transducers 12-1 through 12-9 are coupled to an enclosure 152 and are driven by an Improved 9-Order Bessel Circuit 154 which receives an input signal from an amplifier 16. The second, third, and seventh transducers are driven by in-phase, full-amplitude “+1” signals from the amplifier. The circuit includes a frequency-dependent voltage divider 156, such as a simple shelf circuit, which drives the first transducer 12-1 and the ninth transducer 12-9 with an in-phase “+1/+½” signal which is full-amplitude in a low frequency range and half-amplitude in a high frequency range. A low-pass filter 158 drives the fourth and sixth transducers 12-4, 12-6 with a “+1/0” signal which is in-phase, full-amplitude in a low frequency range and substantially null in a high frequency range. An inverting all-pass filter 160 drives the fifth transducer 12-5 and the eighth transducer 12-8 with a full-amplitude “+/−1” signal which is in-phase in a low frequency range and opposite-phase in a high frequency range.

This version of the improved 9-Order Bessel uses nine transducers and produces nine transducers' worth of sound pressure in a low frequency range, and two transducers' worth of sound pressure in a high frequency range. If conventional voltage dividers were used in place of the frequency-dependent voltage divider, only eight transducers' worth of sound pressure would be produced in the low frequency range.

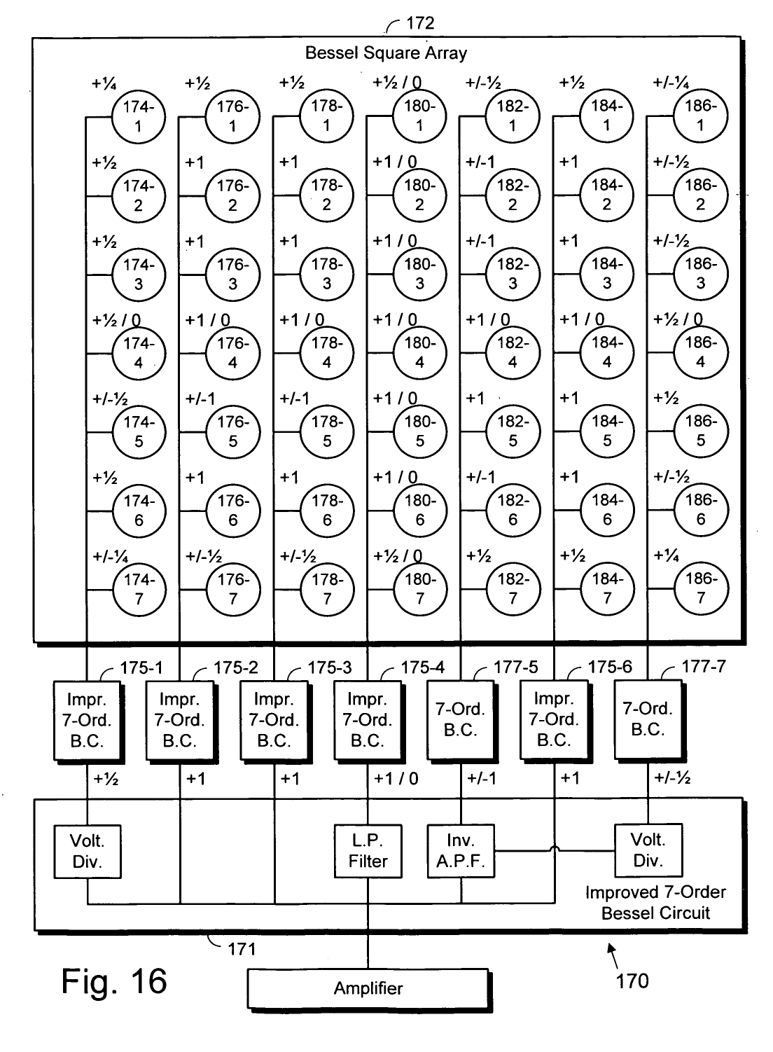

FIG. 16 illustrates an improved 7-Order Bessel square array 170 according to yet another embodiment of the invention. The output of the amplifier is provided to an improved main 7-Order Bessel Circuit 171 which drives five improved 7-Order Bessel Circuits 175 and two conventional 7-Order Bessel Circuits (without the all-pass filter) 177, which in turn drive the transducers 174 to 186 of the array 172 as indicated.

The main Bessel circuit includes a voltage divider which provides a “+½” signal to the first column Bessel circuit 175-1, a low pass filter which provides a “+1/0” signal to the fourth column Bessel circuit 175-4, an inverting all-pass filter which provides a “+/−1” signal to the fifth column Bessel circuit 177-5, and a voltage divider in series with the inverting all-pass filter to provide a “+/−½” signal to the seventh column Bessel circuit 177-7. The second, third, and sixth column Bessel circuits are fed with the “+1” output of the amplifier.

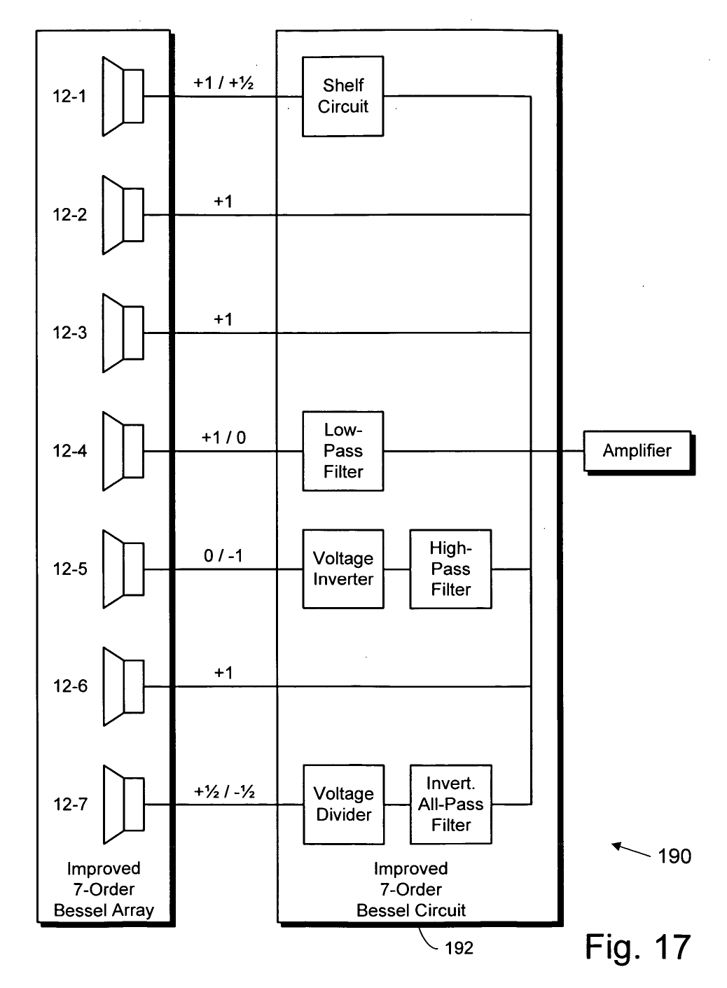

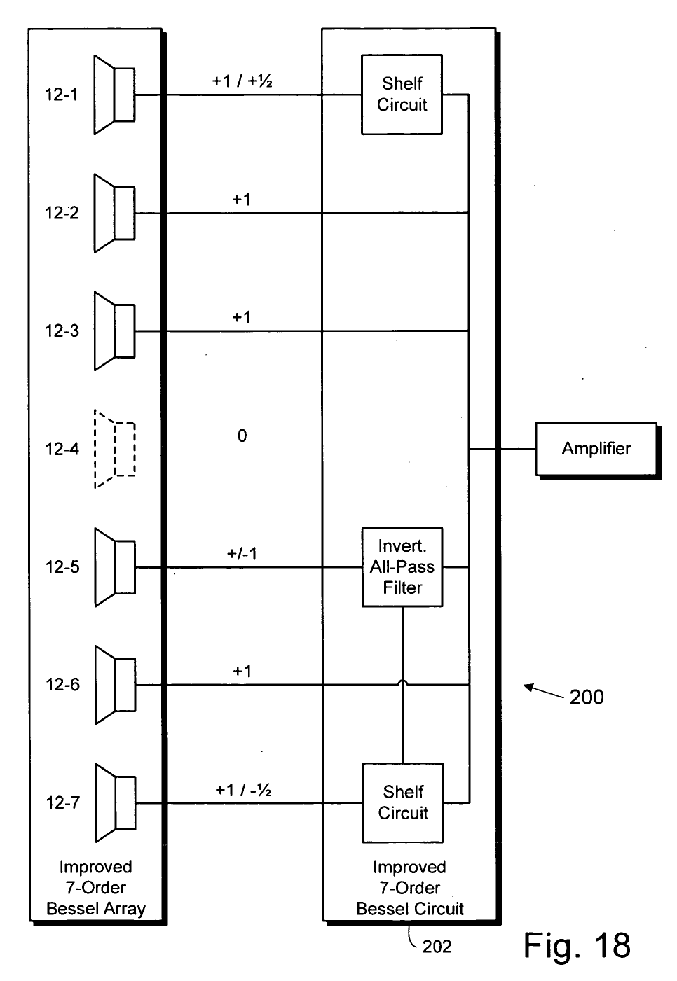

FIG. 17 illustrates another embodiment of an improved 7-Order Bessel array 190, in which an improved Bessel circuit 192 drives seven transducers 12-1 to 12-7. The first transducer 12-1 is driven by a “+1/+½” signal from a shelf circuit. The fourth transducer 12-4 is driven by a “+1/0” signal from a low pass filter, such that it contributes “+1” in the low frequencies, but has the appropriate “0” contribution in the higher frequencies where the Bessel effect is important. The fifth transducer 12-5 is driven by a voltage inverter and high-pass filter in series, such that it contributes “0” (rather than the conventional Bessel “−1”) in the low frequencies, and the desired “−1” in the high frequencies. Alternatively, the fifth transducer could be driven by an inverting all-pass filter to have a “+/−1” characteristic (as shown in FIG. 18). The seventh transducer 12-7 is driven by an inverting all-pass filter and a voltage divider in series, such that it has a “+/−½” characteristic; alternatively, it could be driven by a shelf circuit and an inverting all-pass filter in series to have a “+1/−½” characteristic (as shown in FIG. 18). The second, third, and sixth transducers are directly driven by the amplifier with “+1/+1” signals.

FIG. 18 illustrates a different 7-Order Improved Bessel Array 200 using a different Improved Bessel Circuit 202. A first transducer 12-1 is driven with a “+1/+½” signal provided by a first shelf circuit. A fourth transducer (12-4) would be driven with a “0” signal and is therefore omitted in this embodiment. A fifth transducer 12-5 is driven with a “+/−1” signal from an inverting all-pass filter. The output of the all-pass filter is also fed to a second shelf circuit, to drive a seventh transducer 12-7 with a “+1/−½” signal. The other transducers are driven with “+1” signals directly from the amplifier.

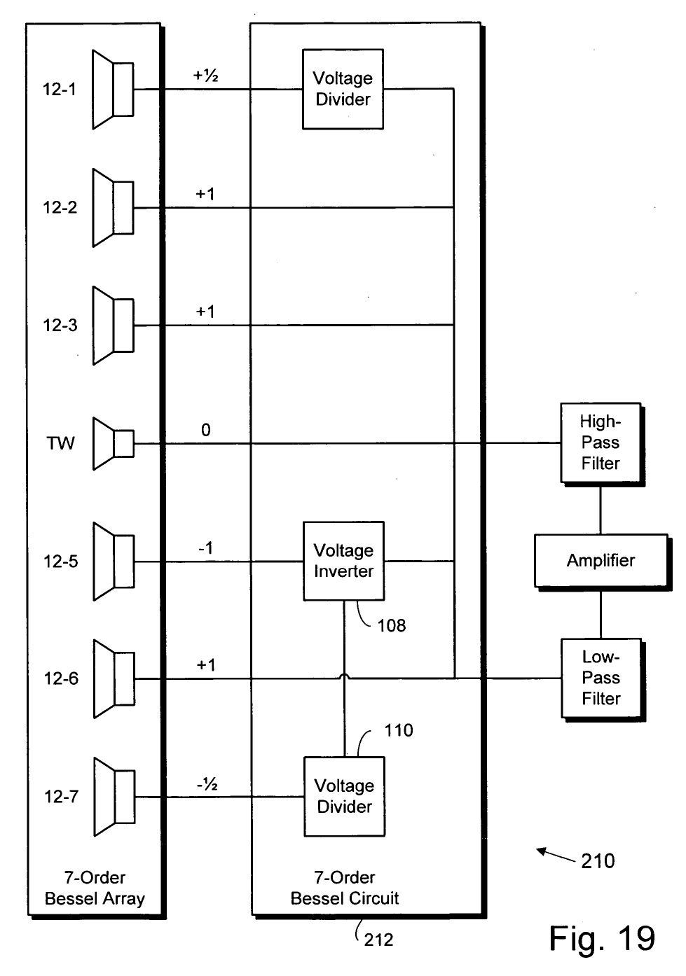

FIG. 19 illustrates another 7-Order Improved Bessel Array 210 used in a 2-way speaker system. The amplifier does not directly power the Bessel circuit. A low-pass filter is designed such that it blocks frequencies above about 2 kHz or whatever crossover frequency the designer selects. The Bessel circuit 212 receives the output of the low-pass filter. A first transducer 12-1 is driven with a “+½” signal from a first voltage divider. A fifth transducer 12-5 is driven with a “−1” signal from a voltage inverter (typically amounting to nothing more than the transducer being wired oppositely versus the others). A second voltage divider is also coupled to receive the output of the voltage inverter, and provides a “−½” signal to a seventh transducer 12-7. The second, third, and sixth transducers are driven directly with “+1” signals.

A high-pass filter is designed such that it blocks frequencies below about 2 kHz or whatever crossover frequency the designer selects. The high-pass filter drives a high frequency transducer, such as a tweeter. In one embodiment, the tweeter is advantageously placed in the position where the fourth transducer would be—that is, the “0” signal position in the Bessel array. (Note that the “0” does not mean that there is no signal provided to the tweeter, only that the Bessel circuit is not providing a signal to it.)

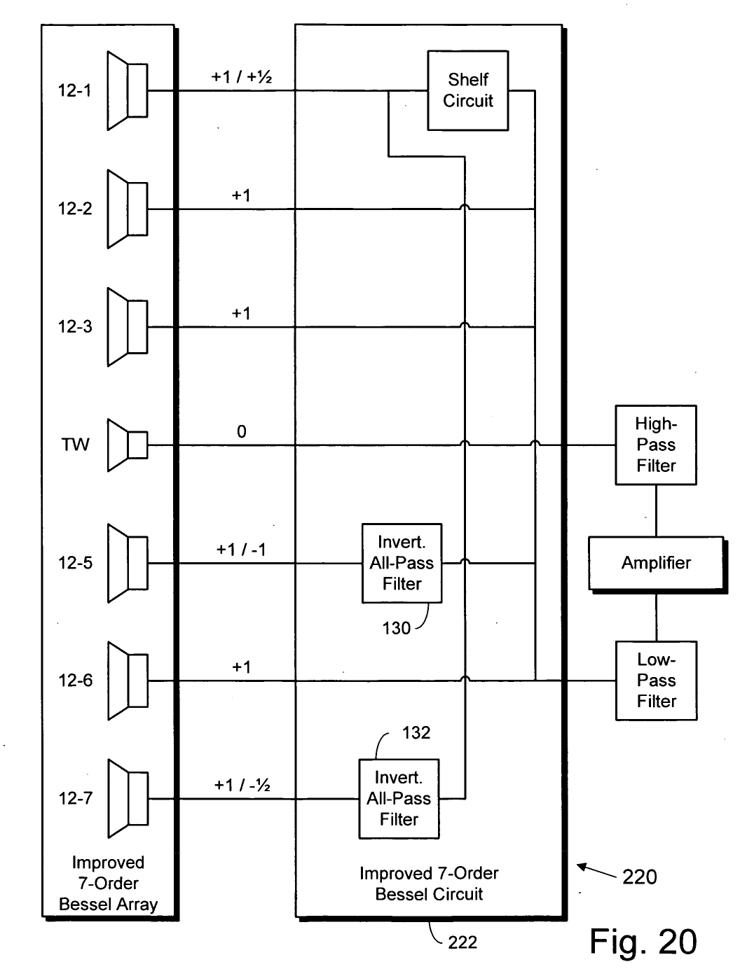

FIG. 20 illustrates an Improved 7-Order Bessel Array 220 using the same tweeter-equipped transducer configuration as in FIG. 19. The tweeter is driven by a high-pass filter, and an Improved Bessel Circuit 222 is driven by a low-pass filter. The first transducer is driven with a “+1/+½” signal from a shelf circuit, the fifth transducer is driven with a “+/−1” signal from an inverting all-pass filter, and the seventh transducer is driven with a “+1/−½” signal from a shelf circuit and an inverting all-pass filter in series. In one embodiment, as shown, there is one shelf circuit for the first and seventh transducers. In other embodiments, the seventh transducer's inverting all-pass filter may be driven by its own shelf circuit.

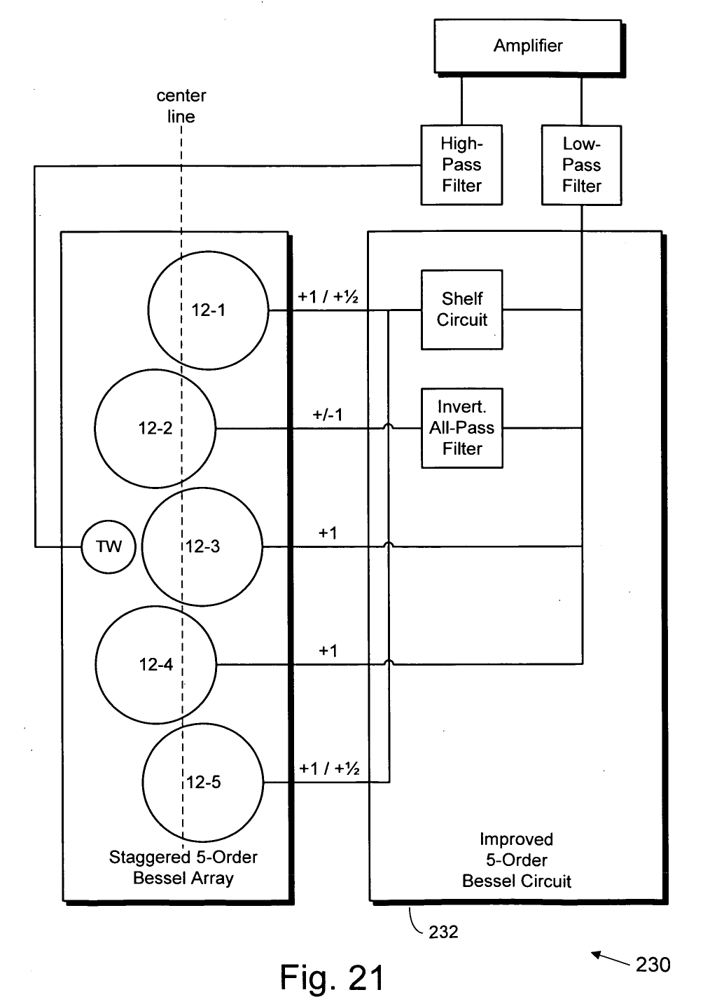

FIG. 21 illustrates a Staggered Bessel Array system 230. A transducer array includes five transducers 12-1 to 12-5 which, rather than being arranged in a conventional straight line, are staggered alternately from an imaginary vertical center line shown as a dashed line in FIG. 21. The odd-numbered transducers are offset in one direction from the center line, and the even-numbered transducers are offset in the opposite direction. In order to maintain the desirable Bessel functionality, the transducers are on equal vertical center-to-center spacing. Offsetting them in the horizontal direction does not significantly affect the Bessel off-axis performance improvement, as long as they are not offset too far. In one embodiment, they are horizontally offset less than one half the radius of one of the transducers. In another embodiment, they are horizontally offset less than the radius. In another embodiment, they are offset less than three-quarters the diameter of one of the transducers. And in yet another embodiment, they are offset less than the diameter.

In some embodiments, a tweeter is added, preferably on the same vertical positioning as the center transducer, which is where the acoustical center of the Bessel array appears to be located. In some such embodiments, the tweeter is advantageously offset in the opposite direction than the center transducer, putting it as close to the center line as possible.

In one such system, there are five transducers in the Bessel array, and a low-pass filter governs the input to the Improved Bessel circuit. The circuit includes a shelf circuit providing a “+1/+½” signal to the first and fifth transducers, and an inverting all-pass filter providing a “+/−1” signal to the second transducer. Other systems may use 7-order or 9-Order Bessel arrays. The offset may be as shown, with every other transducer offset in an opposite direction. Or, the first, fourth, etc. transducers may be offset left, the second, fifth, etc. transducers may be on the center line, and the third, sixth, etc. transducers may be offset right. Or, the transducers may be offset in a zigzag pattern.

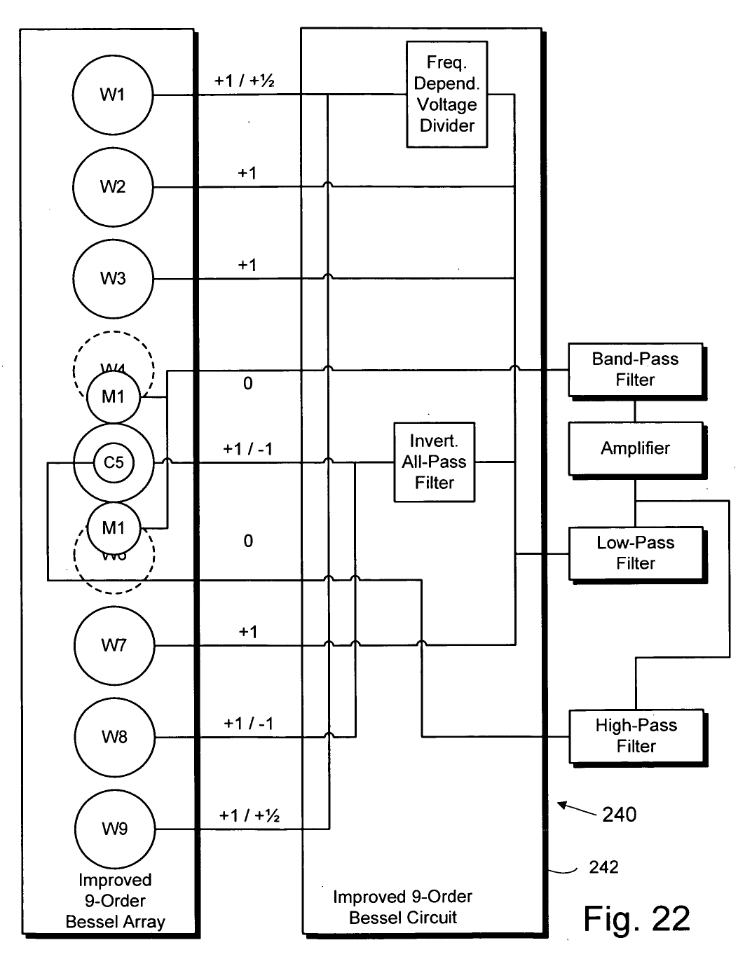

FIG. 22 illustrates an improved 9-Order Bessel Array system 240 according to yet another embodiment of this invention, with an Improved 9-Order Bessel Circuit 242. The

Improved Bessel Array includes woofer or full-range transducers in the first, second, third, seventh, eighth, and ninth positions. The fifth position is occupied by a coaxial transducer whose tweeter is driven by a high-pass filter. The first and ninth transducers W1, W9 are driven with a “+1/+½” signal from a frequency-dependent voltage divider such as a shelf circuit. The woofer of the coaxial in the fifth position, and the eighth transducer W8 are driven by a “+/−1” signal from an inverting all-pass filter. The second, third, and seventh transducers are driven with “+1” signals from the low-pass filter.

The fourth and sixth “0” positions (whose physical positions are marked by dashed circles W4 and W6, partially obscured) are not occupied by the same type of transducer as the first, second, etc. positions. Rather, a pair of mid-range transducers M1, M2 are positioned as close to the coaxial transducer as possible, which puts them closer to the fifth position than the fourth and sixth positions are. That is, the mid-range transducers do not need to be on the same on-center spacing as the woofers. The mid-range transducers are driven by a band-pass filter whose lower cutoff frequency could be set in the 200-1000 Hz range and whose upper cutoff frequency could be set in the 1000-8000 Hz range, or both could be set to whatever frequency ranges the designer chooses.

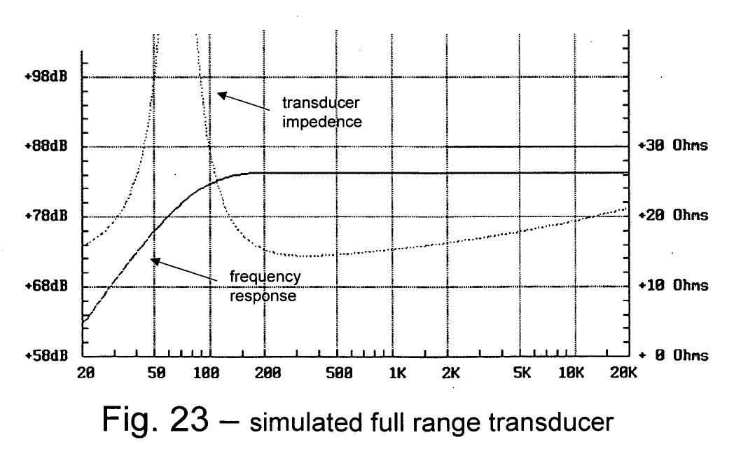

FIG. 23 illustrates a frequency response of a simulated full range transducer modeled as an idealized omni-directional point source. In other words, there is no real-world driver directivity taken into account in the following simulations.

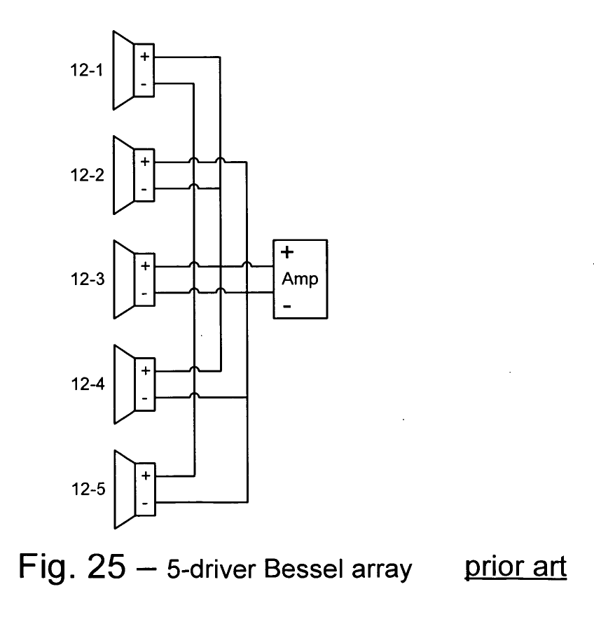

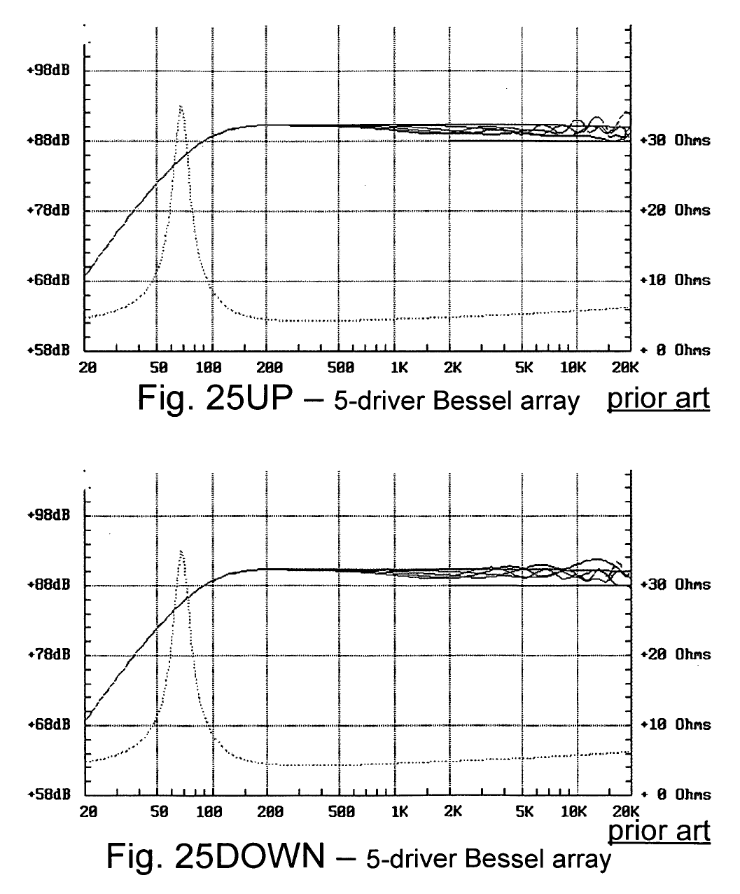

The darker, heavier line is the frequency response, shown from 20 Hz to 20 kHz. The lighter, dotted line is the impedance of the transducer. The frequency response is essentially flat at 84 dB from approximately 150 Hz to 20 kHz. This simulated transducer is used as the basis for the simulated systems whose frequency response is illustrated in FIGS. 25-36.

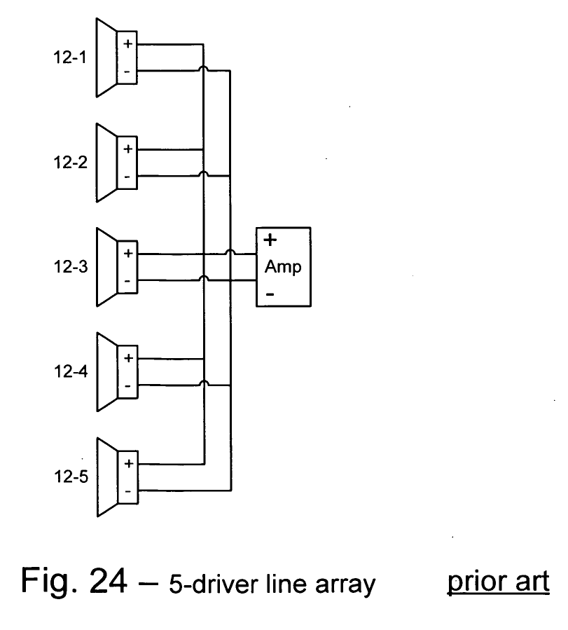

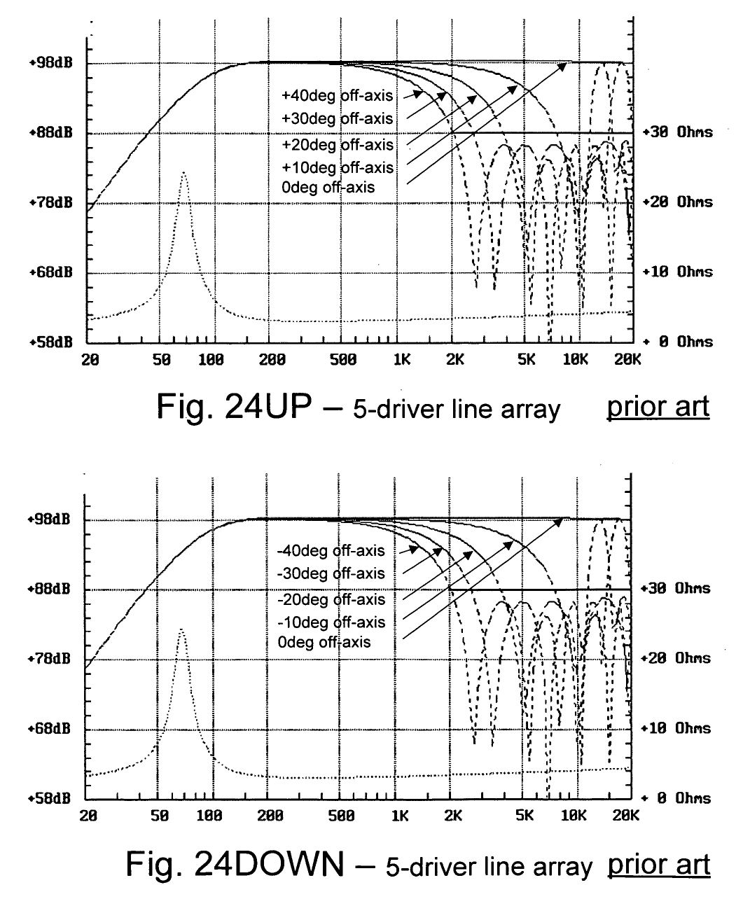

FIG. 24 illustrates 5-transducer simple line array using five copies of the transducer of FIG. 23 with a center-to-center spacing of 4 cm.

FIGS. 24UP and 24DOWN are frequency response graphs generated by a computer simulation analysis of the line array of FIG. 24. The upper graph shows five frequency response curves, measured at 0°, +10°, +20°, +30°, and +40° off-axis, and the lower graph shows five frequency response curves, measured at 0°, −10°, −20°, −31°, and −40° off-axis. 0° (on-axis) is defined to be the position where the axis is centered on the middle (in this case third) driver and perpendicular to the line array.

For purposes of consistency, the line array is (and subsequent arrays in FIG. 25 etc. are) modeled as a vertical array such as those described elsewhere in this patent, and the positive off-axis angles are those above horizontal and the negative off-axis angles are those below horizontal. The upper (positive) angles are more significant than the lower (negative) angles in typical applications in which the listener's ear is more likely to be above the center of the array than below it. In other words, most speakers are placed on the floor rather than on the ceiling. And if a ceiling-mounted array is to be used, it is simply inverted, such that the positive angles are those pointing downward toward the listener and the negative angles are those pointing toward the ceiling.

The frequency response graphs demonstrate the very significant comb filtering and interference patterns which occur in a line array in the higher frequencies—above about 600 Hz in the present example. The farther off-axis, the worse these effects are, and the worse the audible frequency response distortion will be. In the case of the simple line array, the off-axis performance is symmetrical with respect to the positive and negative angles.

In the range roughly between 150 Hz and 600 Hz, the line array's output is extremely flat at 98 dB, a 14 dB improvement over the 84 dB output of the single transducer. The array's impedance is significantly lower than the single transducer, as the five drivers are all coupled in parallel.

FIG. 25 illustrates a modeled conventional 5-transducer Bessel array. The first and fifth transducers are wired in series to achieve the “+½” signal for each, the second transducer is wired backward to achieve the “−1” signal, and the third and fourth transducers are wired in parallel to achieve the “+1” signal.

FIGS. 25UP and 25DOWN illustrate the simulated frequency response at positive off-axis angles (0°, +10°, +20°, +30°, and +40°) and negative off-axis angles (0°, −10°, −20°, −30°, and −40°), respectively. As can be readily observed by comparing FIGS. 25UP and 25DOWN to FIGS. 24UP and 25DOWN, the Bessel array provides a truly remarkable improvement in off-axis performance versus the line array. Unfortunately, however, the output has been rather drastically reduced from 98 dB to 90 dB across the flat region of the frequency range.

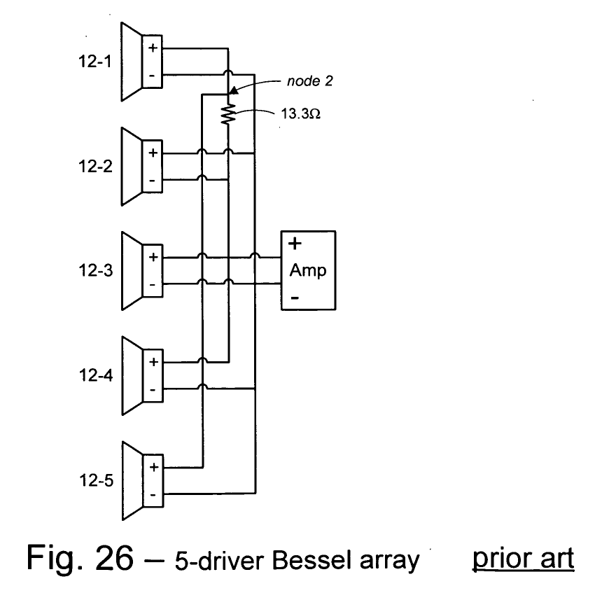

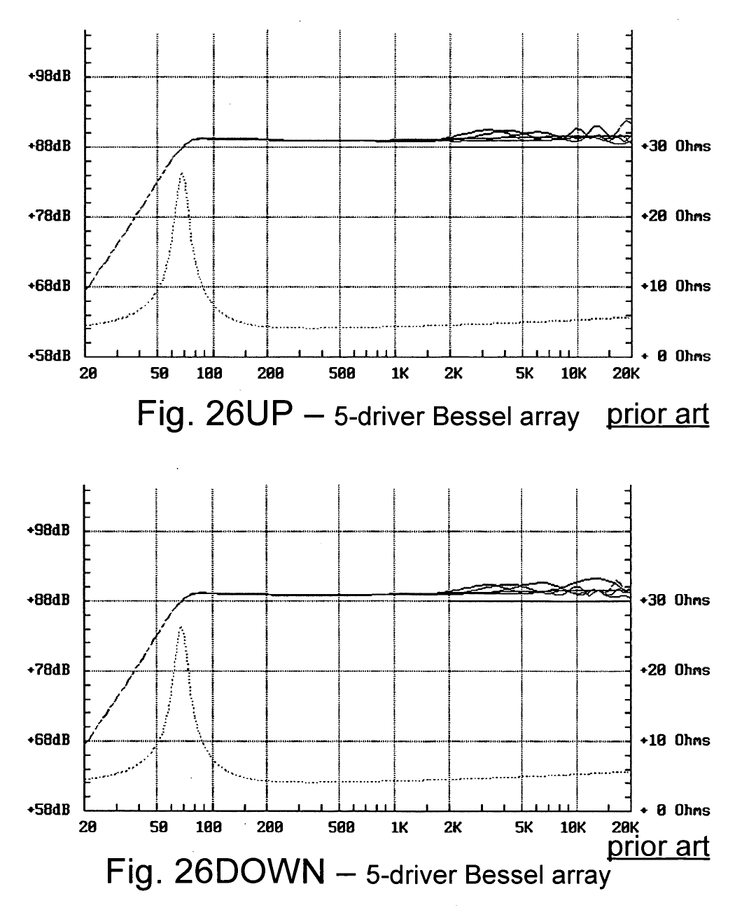

FIG. 26 illustrates a modeled 5-driver Bessel array whose Bessel circuit uses a 13 ohm resistor which connects the “+” amplifier output to the “+” terminals of both the first and fifth transducers, which are connected in parallel.

FIGS. 26UP and 26DOWN illustrate the simulated off-axis frequency response. Compared to the Bessel array of FIG. 25, the array's output has been reduced slightly, by roughly 1 dB, but in exchange for the bass roll-off frequency being extended down from roughly 150 Hz to roughly 75 Hz, and in exchange for the Bessel transition frequency being pushed from roughly 600 Hz to roughly 2000 Hz.

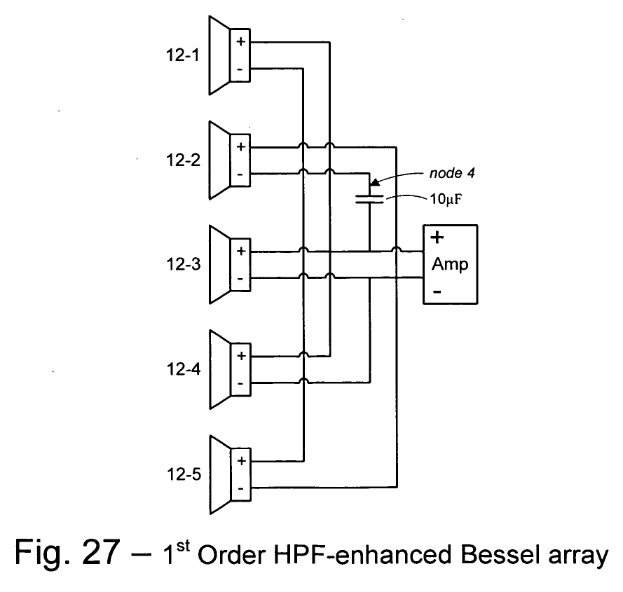

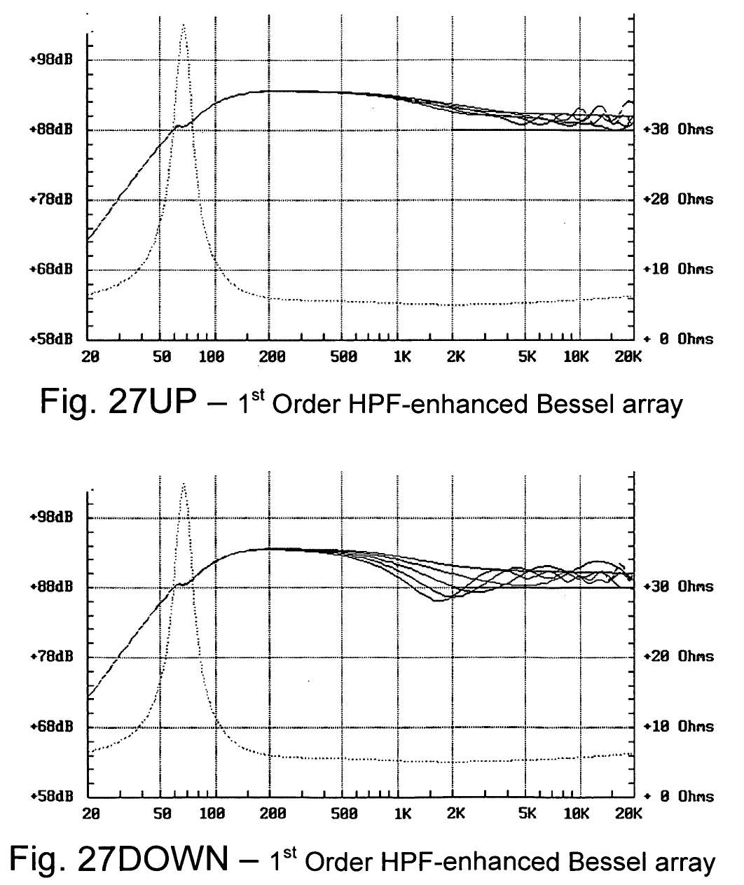

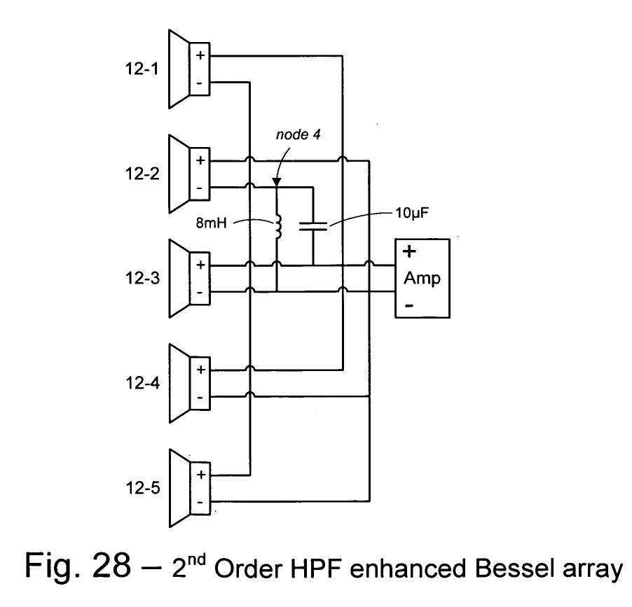

FIG. 27 illustrates a modeled improved Bessel array which adds a first order high-pass filter to its Bessel circuit. In the example shown, the HPF consists of a 10 μF capacitor coupled between the amplifier's “+” output and the second transducer's “−” terminal, providing the “0/−1” input.

FIGS. 27UP and 27DOWN illustrate that the simulated output of the array has been raised from around 90 dB of FIG. 25 to almost 94 dB for much of the mid-bass frequency range between 100 Hz and 1 kHz. The negative off-axis angle frequency response shows a less uniform upper end response than that of the conventional Bessel array, in exchange for this very desirable 4 dB improvement in output.

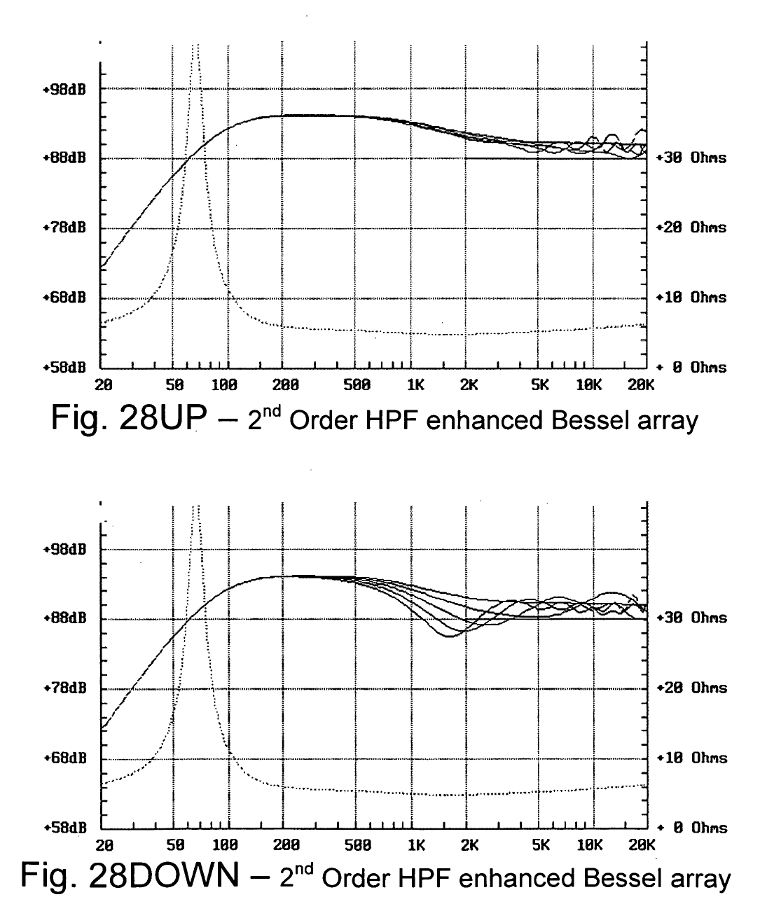

FIG. 28 illustrates a modeled improved Bessel array having a second order high pass filter, which consists of a 10 μF capacitor coupled between the amplifier's “+” output and the “−” terminal of the second transducer, and an 8 mH inductor coupled between the amplifier's “−” output and the “−” terminal of the second transducer.

FIGS. 28UP and 28DOWN illustrate the simulated frequency response. The notch around 60 Hz has been removed, and there is almost a 1 db increase from 200 Hz to 500 Hz.

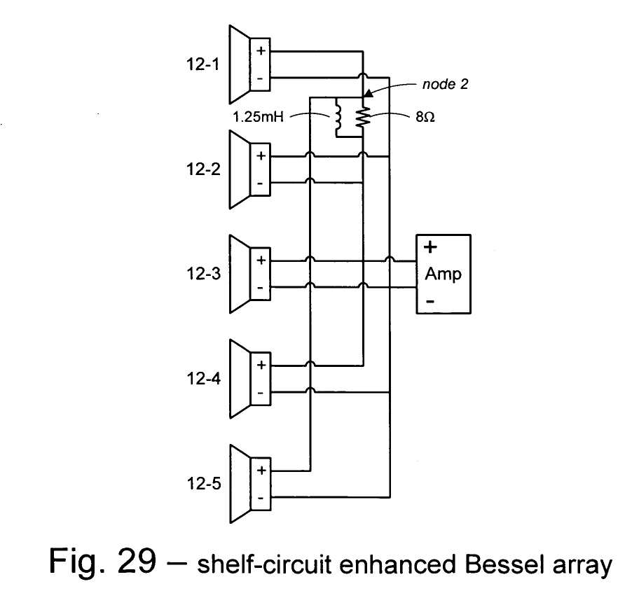

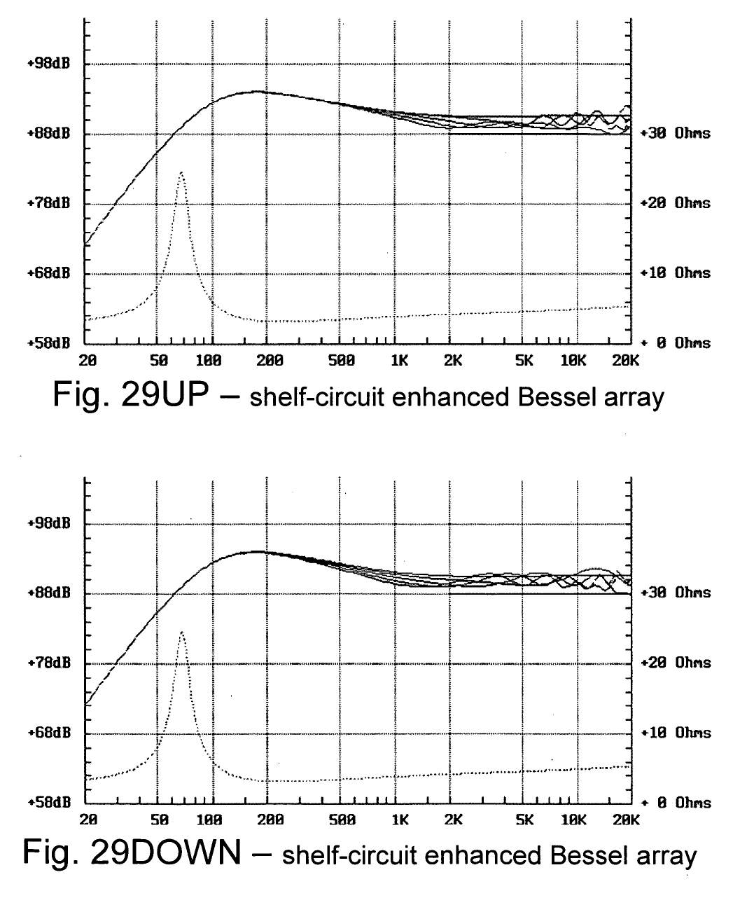

FIG. 29 illustrates an improved Bessel array in which the Bessel circuit includes a shelf circuit. A 1.25 mH inductor and an 8 ohm resistor are coupled in parallel between the amplifier's “+” output and the “+” terminals of the first and fifth transducers.

FIGS. 29UP and 29DOWN illustrate the simulated frequency response. As compared to FIG. 27, the negative off-axis frequency response has been significantly improved, and the anomalous notch around 65 Hz has been removed, but the tradeoff is that the output gain begins to taper off rather quickly above 200 Hz, whereas in FIG. 27 it stayed fairly flat out to 800 Hz or so.

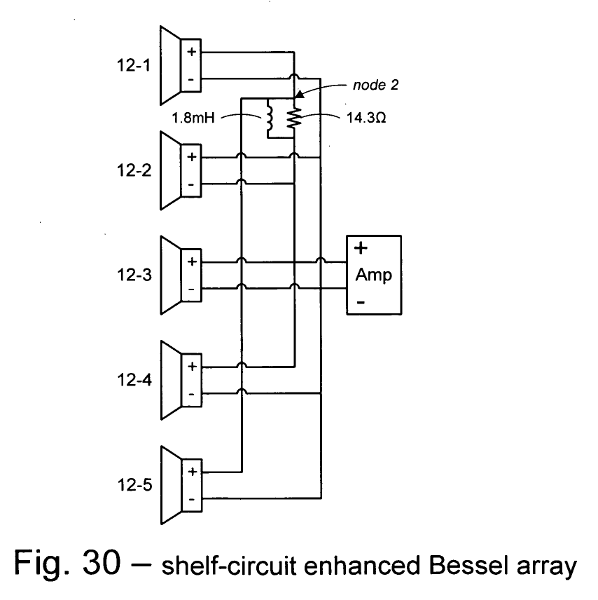

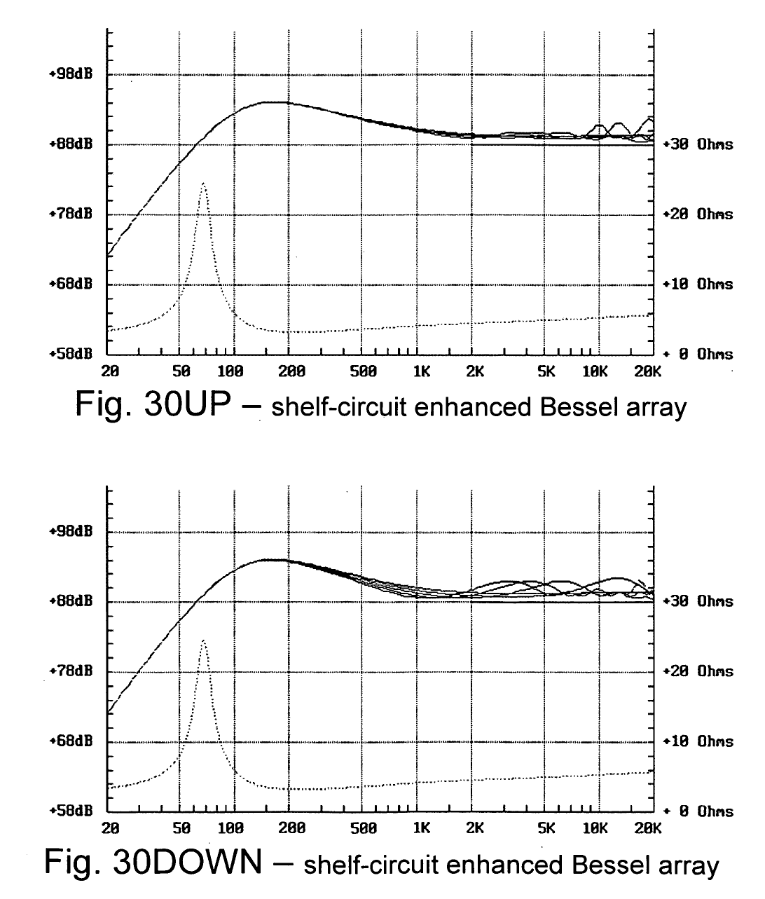

FIG. 30 illustrates a similar, improved Bessel array in which the Bessel circuit includes a shelf circuit consisting of a 1.8 mH inductor and a 14.3 ohm resistor, and which is otherwise the same as that of FIG. 29. FIGS. 30UP and 30DOWN demonstrate that the positive off-axis frequency response has been tightened up.

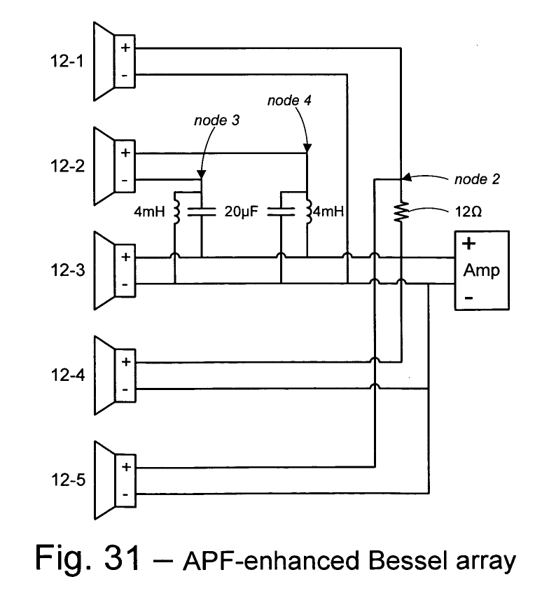

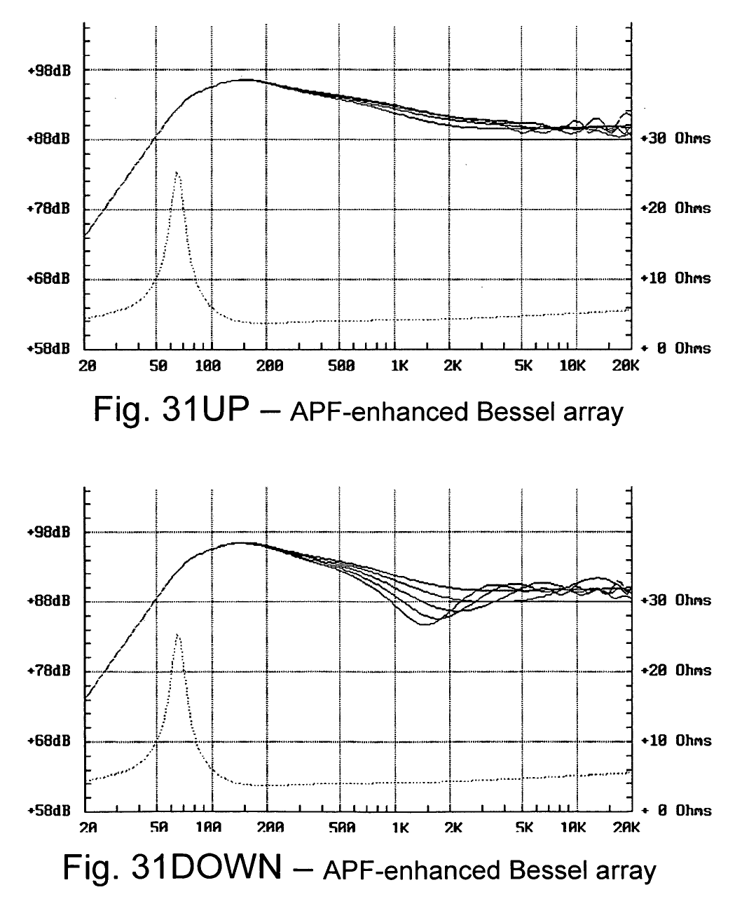

FIG. 31 illustrates an improved Bessel array including an all-pass filter. A 20 μF capacitor is coupled between the amplifier's “+” output and the “−” terminal of the second transducer. A 4 mH inductor is coupled between the amplifier's “−” input and the “−” terminal of the second transducer. A second 20 μF capacitor is coupled between the “+” terminal of the second transducer and the amplifier's “−” output. A second 4 mH inductor is coupled between the amplifier's “+” output and the “+” terminal of the second transducer. A 12 ohm resistor is coupled between the amplifier's “+” output and the “+” terminals of the first and fifth transducers.

FIGS. 31UP and 31DOWN demonstrate that, as compared to FIG. 30, the peak output has been increased from 94 dB to 96 dB.

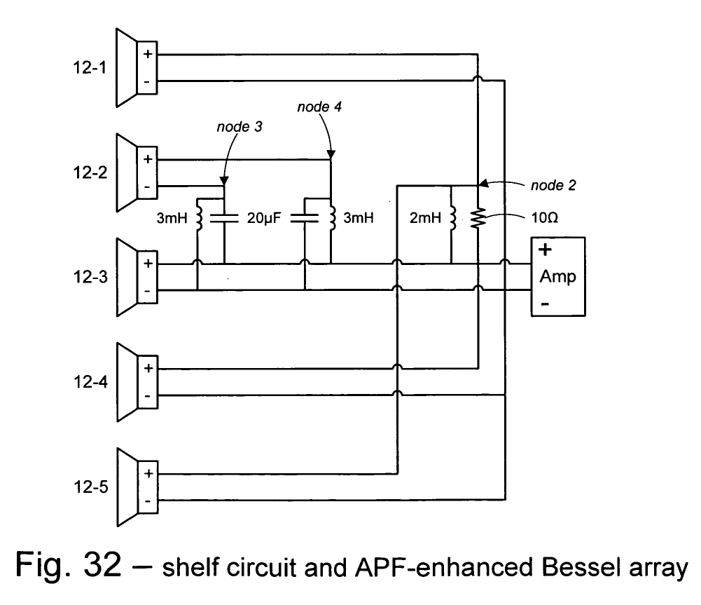

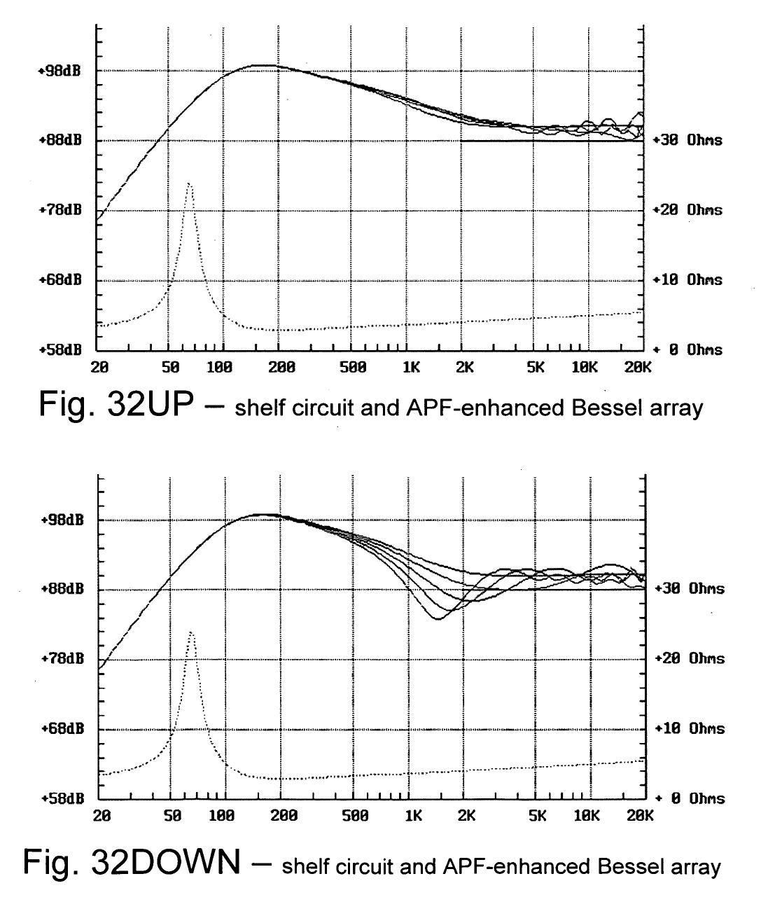

FIG. 32 illustrates an improved Bessel array in which the Bessel circuit uses both a shelf circuit and an all-pass filter. The circuit is very similar to that of FIG. 31, except that the inductors have been reduced from 4 mH to 3 mH, the resistor has been reduced from 12 ohm to 10 ohm, and a 2 mH inductor has been added in parallel with it, between the amplifier's “+” output and the “+” terminals of the first and fifth transducers.

FIGS. 32UP and 32DOWN demonstrate that, as compared to FIG. 31, the peak output has further been increased to almost 99 dB.

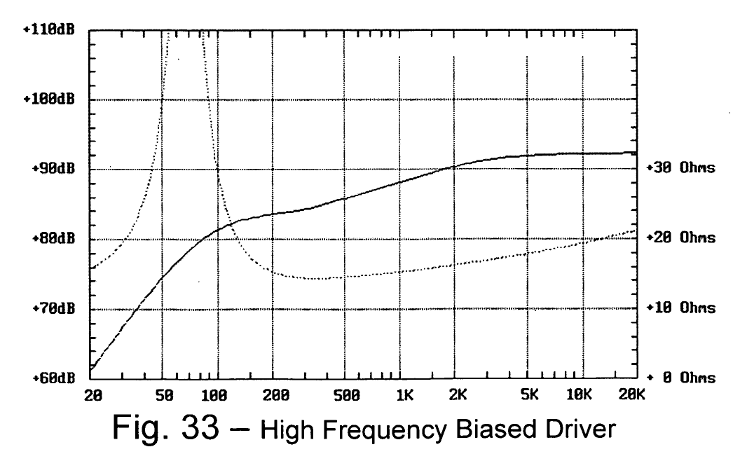

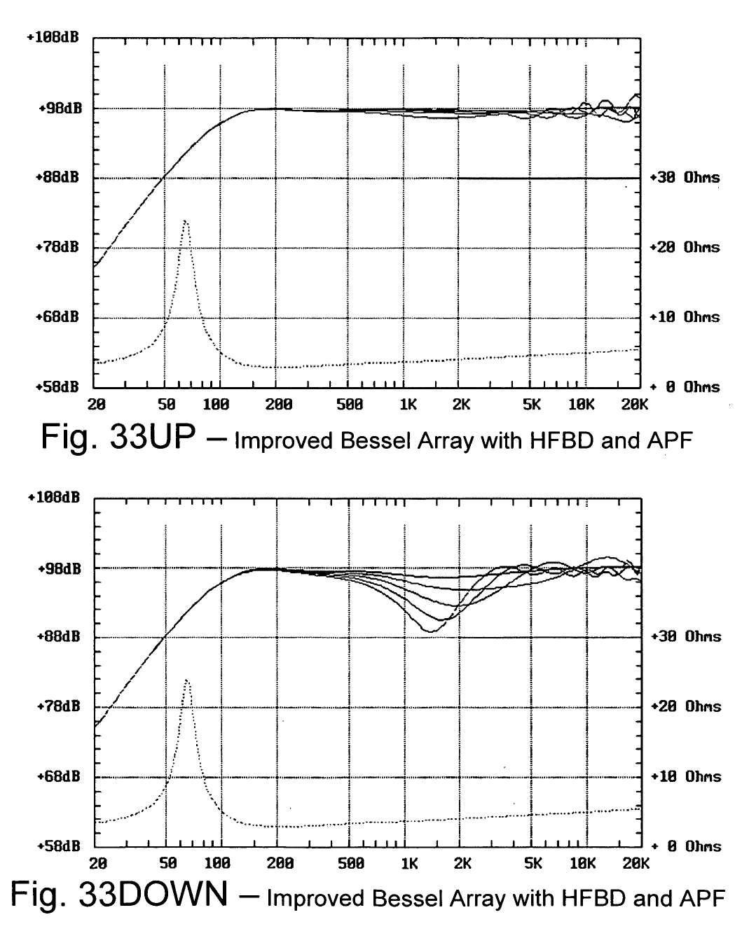

FIG. 33 illustrates a frequency response of a simulated high frequency biased driver modeled as an idealized omni-directional point source. Horn loaded drivers are one example of this sort of “bright” transducer.

In the Improved Bessel Array of FIG. 5, the output is 4 transducer units in the low frequencies, and 2 transducer units in the high frequencies. In FIG. 11, the output is 5 transducer units in the low frequencies, and 2 transducer units in the high frequencies. In FIG. 13, the output is 6 transducer units in the low frequencies, and 2 transducer units in the high frequencies. In FIG. 15, the output is 9 transducer units in the low frequencies, and 2 transducer units in the high frequencies. Using a “bright” transducer, whose high frequency output is louder than its low frequency output, is one way for the designer to balance the output of the Improved Bessel Array.

FIGS. 33UP and 33DOWN illustrate the simulated frequency response of a 5-driver Improved Bessel Array using an all-pass filter (such as in FIG. 5) and the high frequency biased driver of FIG. 33. At positive off-axis listening angles, the output is remarkably flat at 98 dB from 150 Hz upward.

### 4-Transducer Reduced Bessel Array

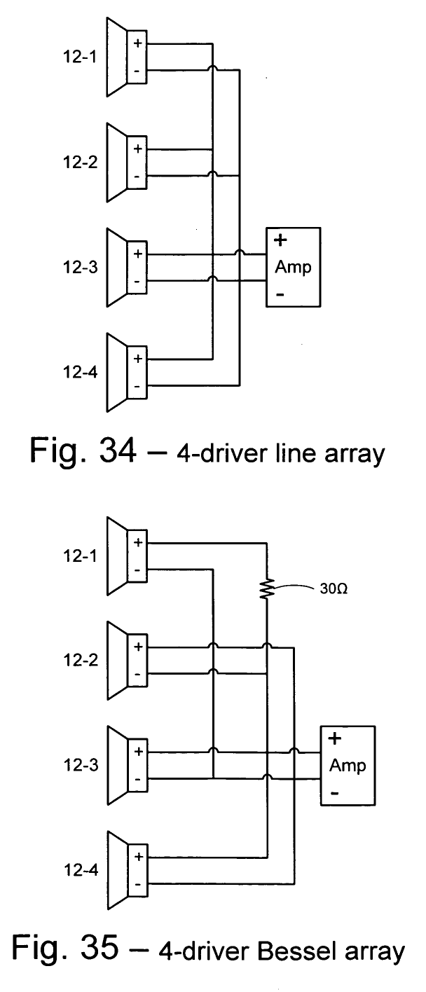

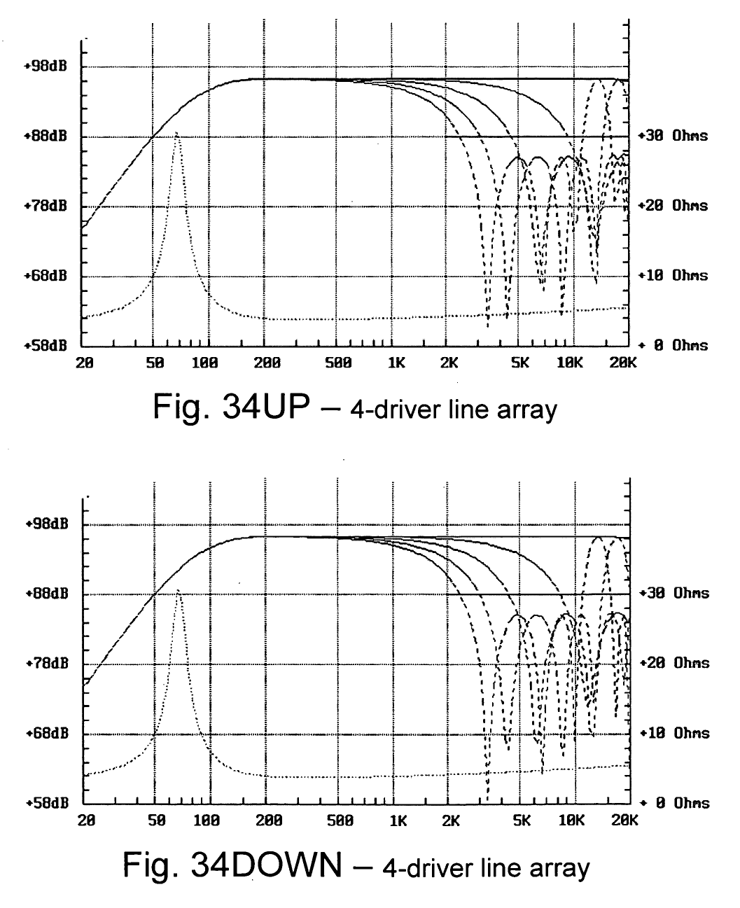

FIG. 34 illustrates a conventional 4-driver line array. FIGS. 34UP and 34DOWN illustrate its simulated frequency response. Its output is roughly 96 dB, and it begins to exhibit significant comb filtering and interference patterns above about 1 kHz.

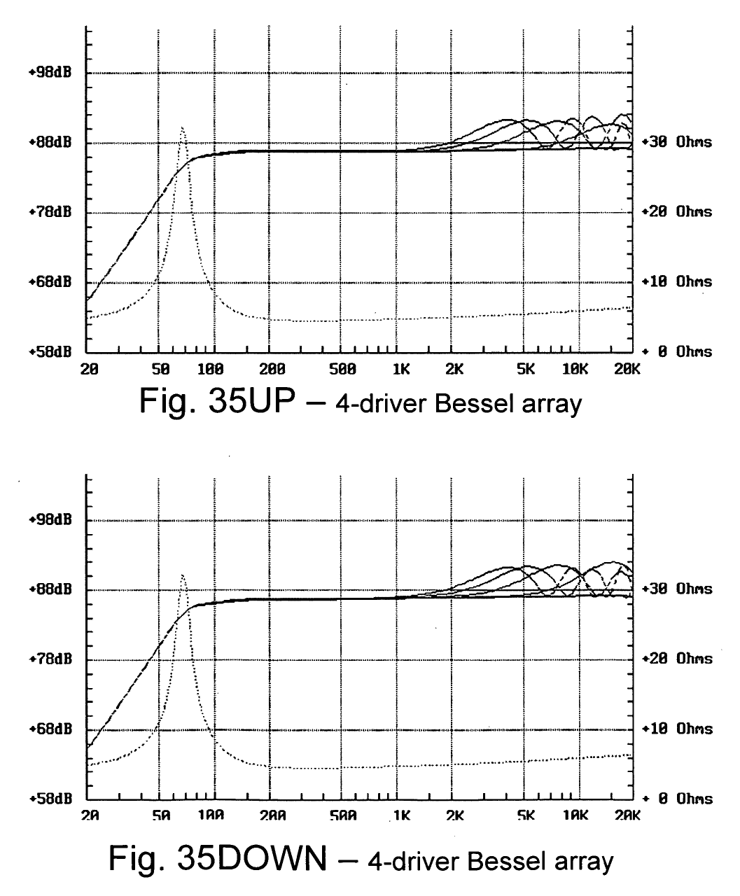

FIG. 35 illustrates a 4-transducer Reduced Bessel Array. The term “Reduced Bessel” is used to suggest that the array uses less than the full 5, 7, or 9, etc. transducer complement taught by the known Bessel array art.

The array uses four transducers 12-1 to 12-4 on equal on-center spacing, and a Reduced Bessel circuit. In one embodiment, the circuit includes a 30 ohm resistor coupled between the amplifier's “+” output and the “+” terminal of the first transducer. The first transducer's “−” terminal is coupled to the amplifier's “−” output. Thus, the first transducer is fed a substantially reduced (less than “+1”) signal. The third and fourth transducers are fed “+1” signals with their “+” terminals are coupled to the amplifier's “+” output and their “−” terminals coupled to the amplifier's “−” output. The second transducer is fed a “−1” signal with its “−” terminal coupled to the amplifier's “+” output and its “+” terminal coupled to the amplifier's “−” output.

FIGS. 35UP and 35DOWN show the simulated off-axis frequency response of the 4-transducer Reduced Bessel Array. From about 80 Hz to about 1200 Hz, its output is just above 86 dB, versus about 96 dB of the FIG. 33 line array. However, its off-axis frequency response is remarkably improved, compared to that of the simple line array. Whereas the line array transitions into a heavy comb filter pattern above about 1.5 kHz, the Reduced Bessel array actually exhibits an off-axis average output rise above about 1.5 kHz, with a relatively small degree of comb filtering which nevertheless only knocks the output down to the 86 dB level. The skilled designer will be able to use this to his advantage, as a means of compensating for the high frequency directivity of real world drivers.

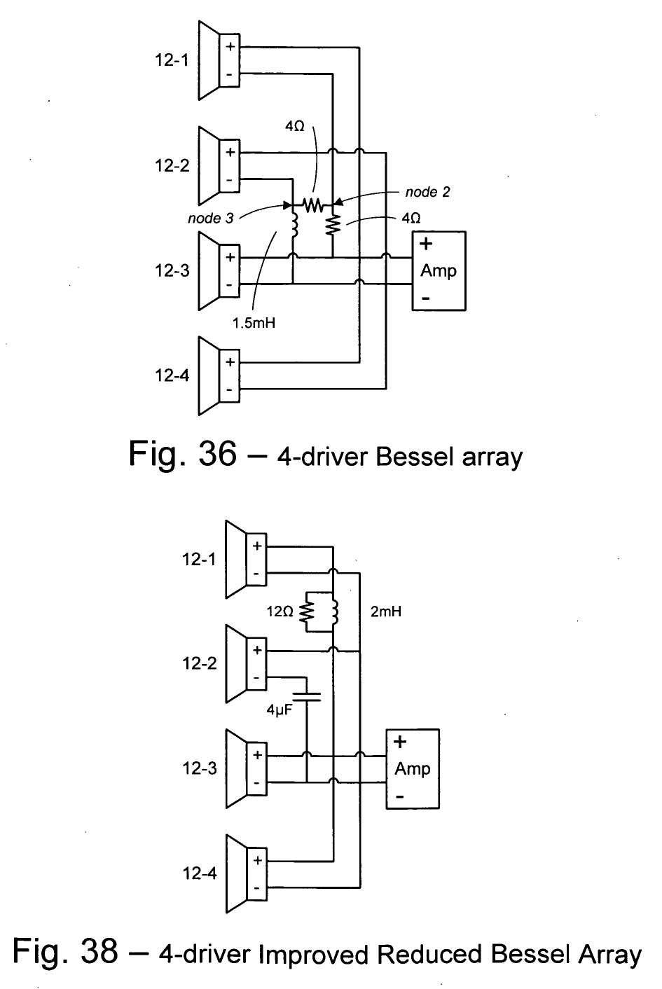

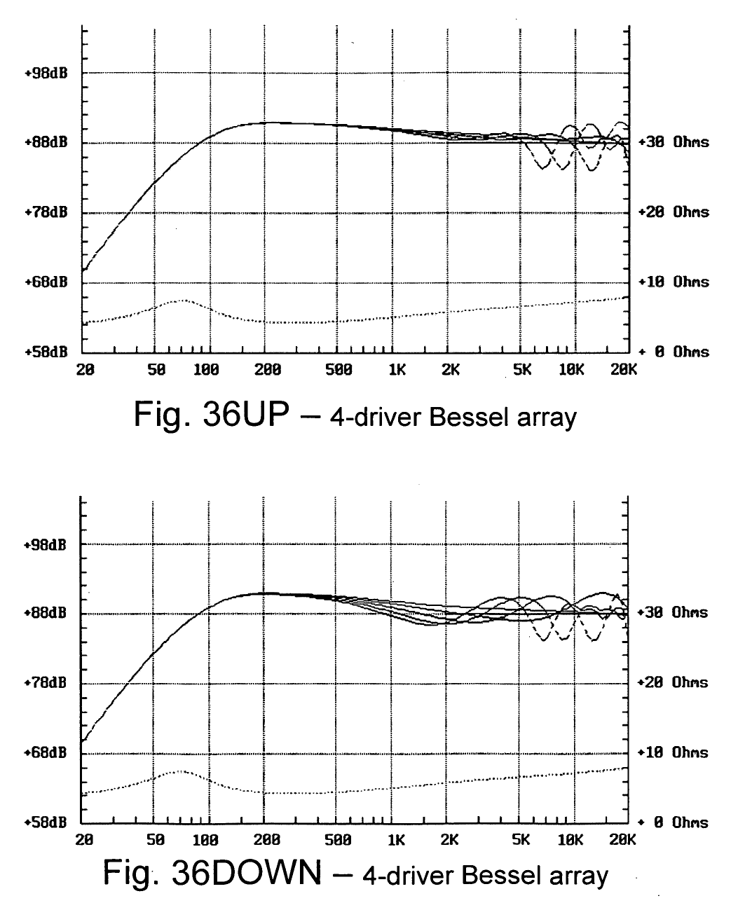

FIG. 36 illustrates a 4-transducer Reduced Bessel Array according to another embodiment of this invention, utilizing a series R-L bypassed across the second transducer. The “+” terminals of the first, third, and fourth transducers are coupled to the amplifier's “+” output, and the “−” terminals of the third and fourth transducers are coupled to the amplifier's “−” output. The third and fourth transducer thus receives “+1” signals. The “+” terminal of the second transducer is coupled to the amplifier's “−” output. The “−” terminal of the second transducer is coupled via a series-connected 1.5 mH inductor and 4 ohm resistor to the amplifier's “−” output, and via another 4 ohm resistor to the amplifier's “+” output. The first transducer's “−” terminal is coupled to the “−” terminal of the second transducer and to the amplifier's “+” output.

FIGS. 36UP and 36DOWN illustrate the simulated frequency response output of the 4-transducer Reduced Bessel Array. Output has been raised to about 91 dB, versus the approximately 87 dB output of the FIG. 35 array.

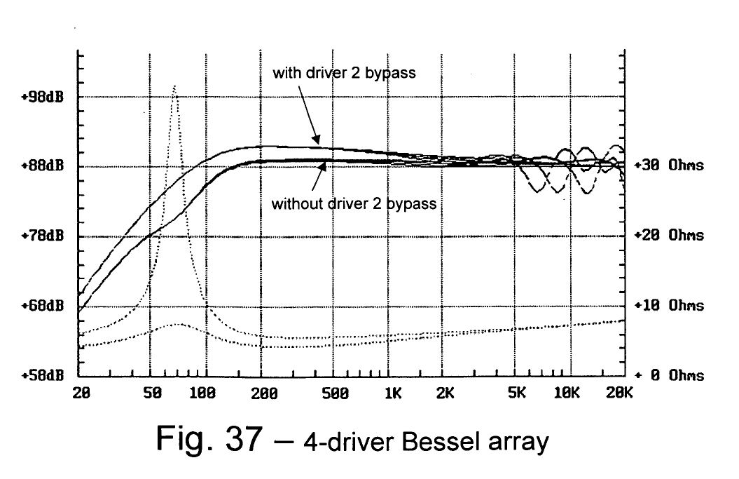

FIG. 37 shows the FIG. 36UP results with and without the series R-L active, overlaid for easier comparison.

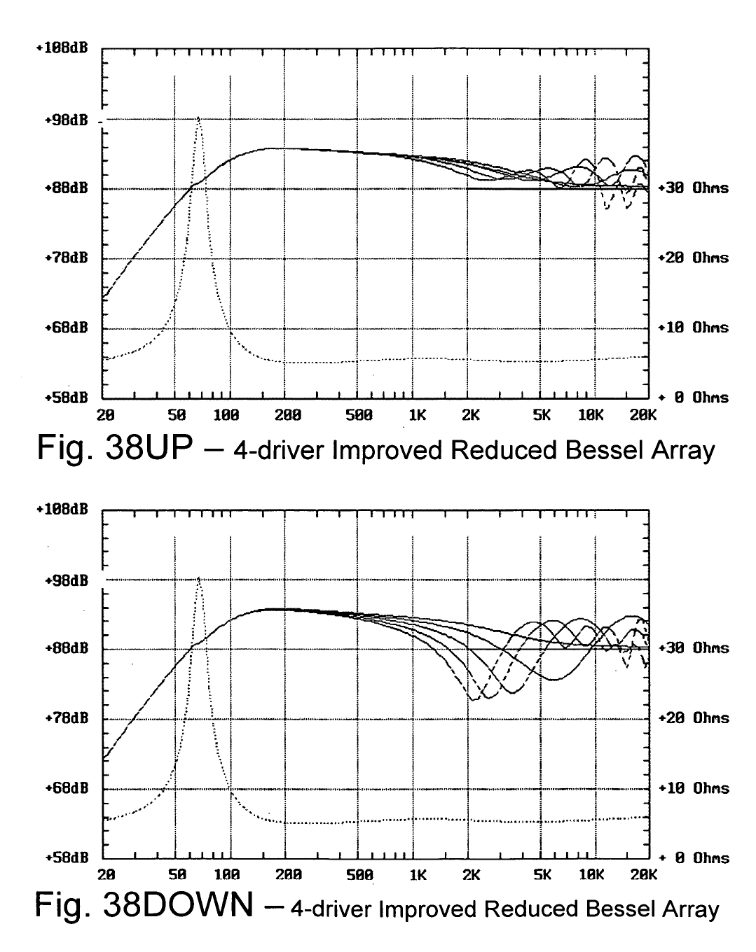

FIG. 38 shows a 4-driver Improved Reduced Bessel Array. A 4 μF capacitor is coupled between the amplifier's “−” output and the “−” terminal of the second transducer. A 12 ohm resistor and a 2 mH inductor are coupled in parallel between the amplifier's “+” output and the “+” terminal of the first transducer. FIGS. 38UP and 38DOWN illustrate the simulated frequency response output of the array.

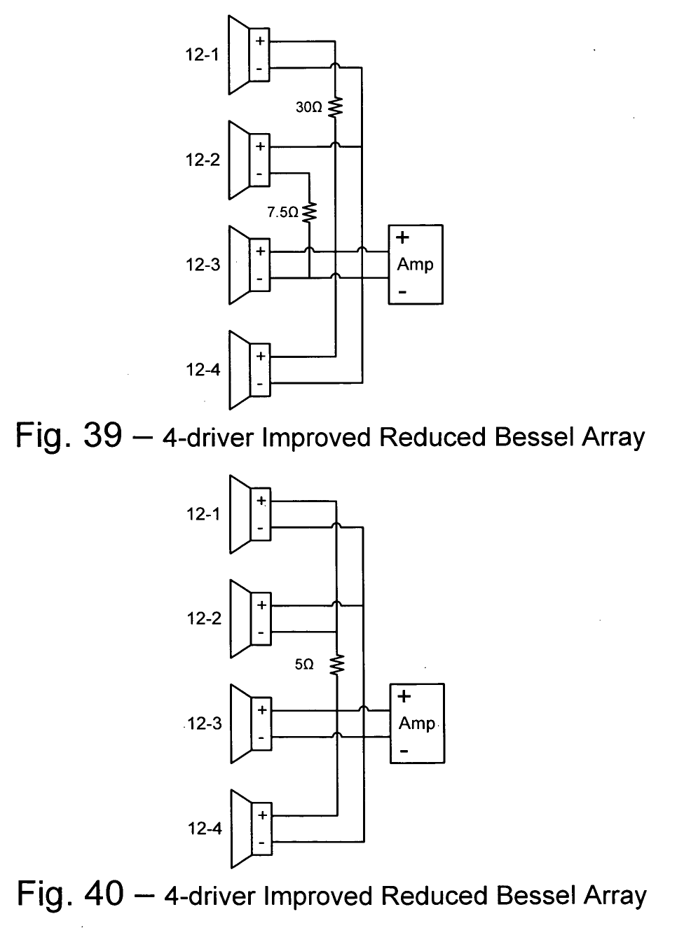

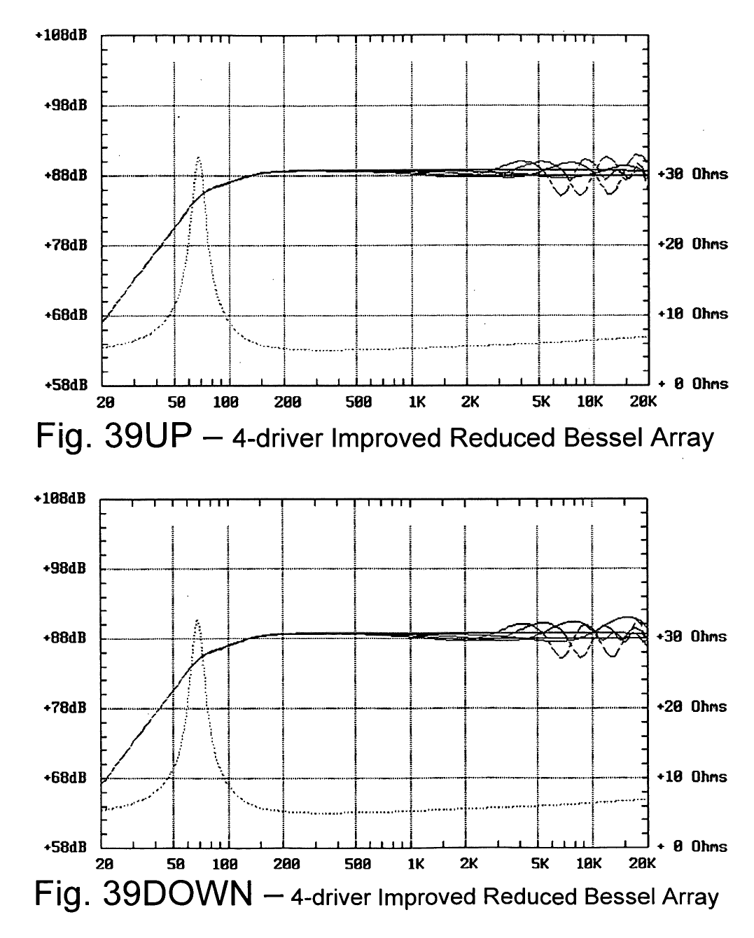

FIG. 39 shows another 4-driver Improved Reduced Bessel Array. A 7.5 ohm resistor is coupled between the amplifier's “−” output and the “−” terminal of the second transducer. A 30 ohm resistor is coupled between the amplifier's “+” output and the “+” terminal of the first transducer. FIGS. 39UP and 39DOWN illustrate the simulated frequency response output of the array.

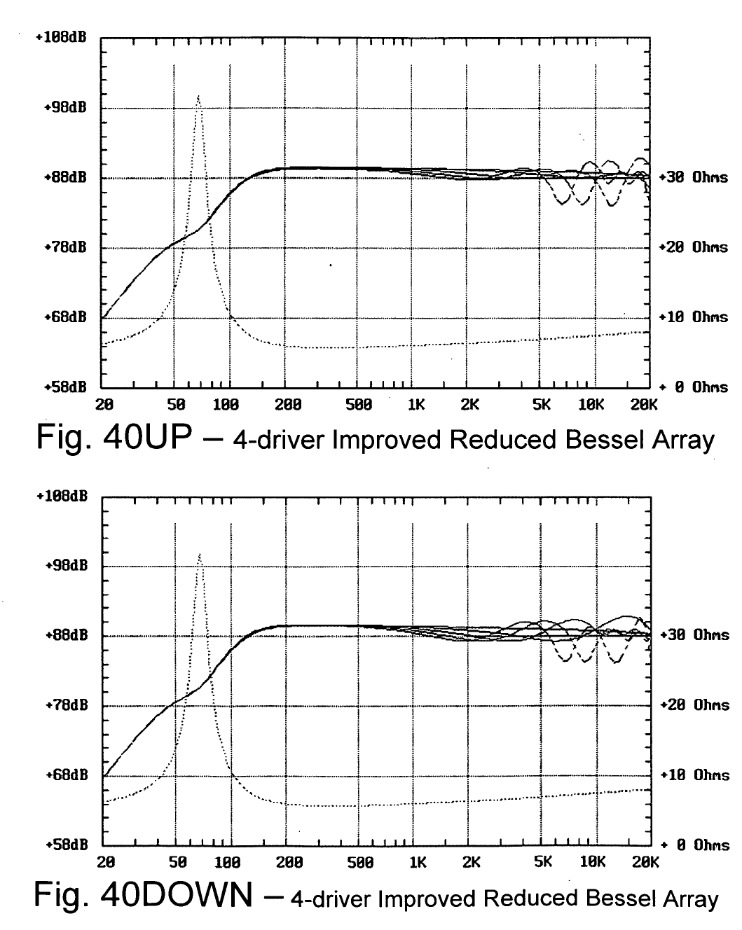

FIG. 40 shows yet another 4-driver Improved Reduced Bessel Array. A 5 ohm resistor is coupled between the amplifier's “+” output and both the “+” terminal of the first transducer and the “−” terminal of the second transducer. FIGS. 40UP and 40DOWN illustrate the simulated frequency response output of the array.

In other configurations, the Reduced Bessel Array principle can be applied to a 7-Order Bessel, using 6 transducers, or to a 9-Order Bessel, using 8 transducers, and so forth. Advantageously, one of the endmost transducers, and preferably the bottom transducer, is omitted.

### Pre-Amplifier Bessel Circuit

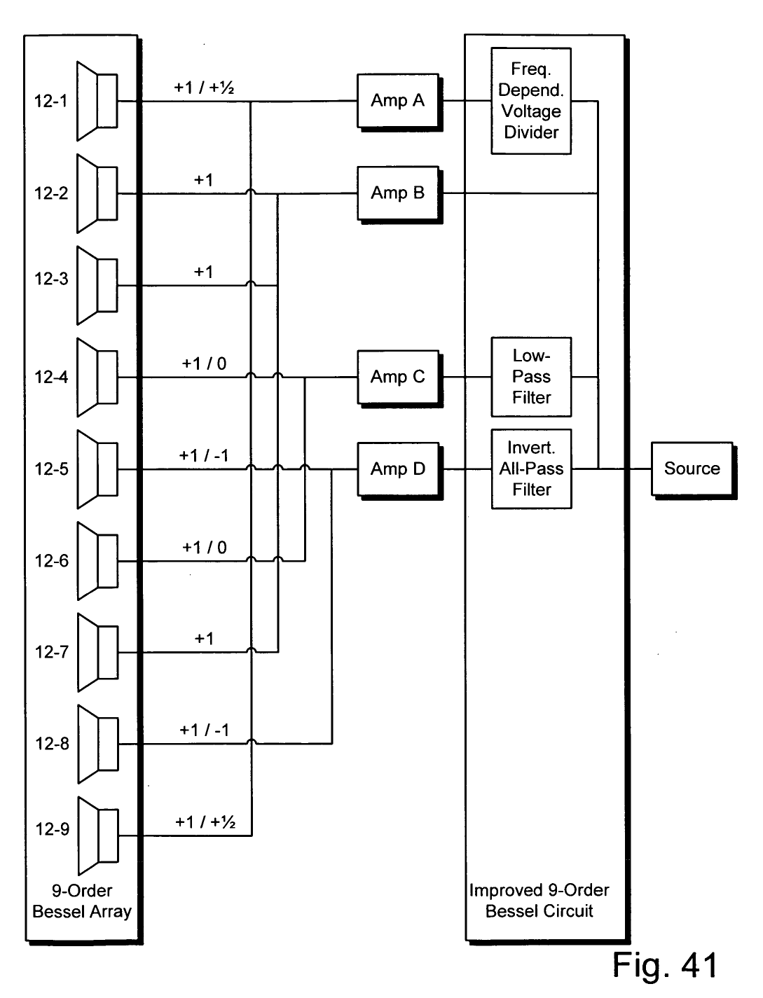

FIG. 41 illustrates an Improved 9-Order Bessel Array in which the Bessel functionality is provided “upstream” from the amplifier section. An input signal is provided from a source such as a CD player, radio, or what have you. This input signal is fed into an Improved 9-Order Bessel Circuit, and the outputs of the Bessel are then fed into the amplifier section of the system.

In some embodiments, the Bessel circuitry comprises conventional passive analog components such as resistors, capacitors, and inductors. In some such embodiments, the source provides an analog signal. In others, the source provides a digital signal which is converted into an analog signal by a digital-to-analog converter (not shown) at the input to the Bessel circuit.

In other embodiments, the Bessel functionality is provided by digital logic such as a digital signal processor executing a codec program. In some such embodiments, the source provides a digital signal. In others, the source provides an analog signal which is converted into a digital signal by an analog-to-digital converter (not shown) at the input to the Bessel circuit.

If the Bessel circuit is done digitally, its output is converted to analog either at the output of the Bessel circuit or at the input of the amplifier stage.

The amplifier stage includes a plurality of amplifiers which, although they operate separately upon their respective signal paths, may be under a common gain control mechanism (not shown). A first amplifier (Amp A) is fed by a frequency-dependent voltage divider and outputs a “+1/+½” signal to the first transducer. It may also provide that signal to the ninth transducer. Or, the ninth transducer may have its own amplifier, but that is a more expensive solution. A second amplifier (Amp B) is fed from the source and provides a “+1” signal to the second transducer, and advantageously also to the third and seventh transducers. A third amplifier (Amp C) is fed by a low pass filter and provides a “+1/0” signal to the fourth transducer, and advantageously also to the sixth transducer. A fourth amplifier (Amp D) is fed by an inverting all pass filter and provides a “+/−1” signal to the fifth transducer, and advantageously also to the eighth transducer.

Each amplifier provides a single “class” or characterization of signal.

### Dual Voice Coil Bessel Arrangement

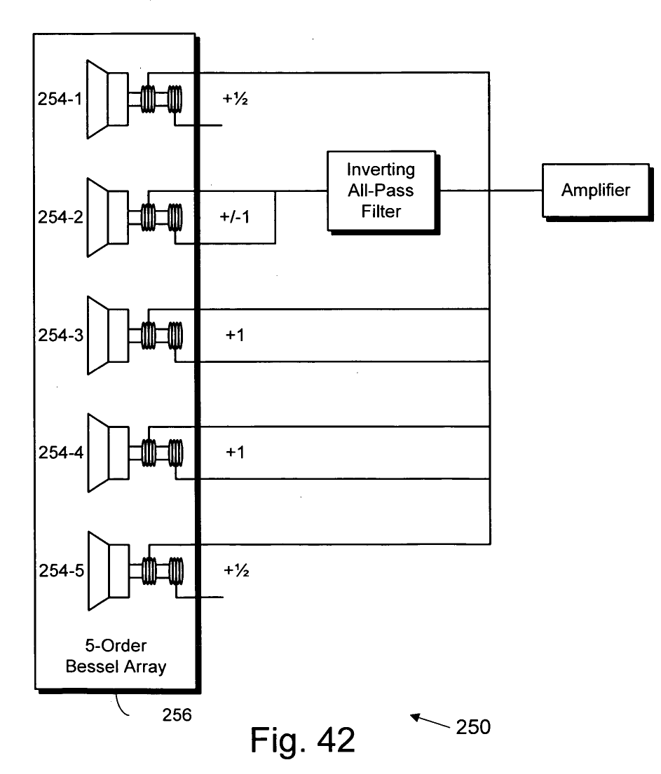

FIG. 42 illustrates an Improved 5-Order Bessel Array system 250 in which each of the transducers 254 is of the dual voice coil variety. Although the voice coils are stylistically shown as being arranged at different axial positions, they may more typically be wound one on top of the other.

The amplifier signal is fed to both voice coils of the transducers at the “+1” positions, but to only one voice coil of the transducers at the “+½” positions. With only half of the active voice coil windings as the other transducers, the first and fifth transducers automatically assume the “+½” value without any special circuitry. In some embodiments, those two transducers are identical to the other three. In other embodiments, those two transducers are cost reduced by omitting the unused voice coil.

In one embodiment, the second transducer is fed by an inverting all-pass filter such that it has a “+/−1” characteristic. In another embodiment, the second transducer is simply connected in reverse polarity to the amplifier and has a “−1” characteristic (in which case the array functions as a simple Bessel Array and not as an Improved Bessel Array).

The same dual winding configuration may also be used with 7-Order, 9-Order, etc. Bessel arrays.

### CONCLUSION

The skilled reader will appreciate that the drawings are for illustrative purposes only, and are not scale models of optimized transducer systems.

While the invention has been described with reference to embodiments in which it is configured as an audio speaker, in other embodiments it may be configured as a microphone, or other such apparatus which may be characterized as an electromagnetic transducer.

The term “square” should not be interpreted to limit the invention to e.g. 5×5 Bessel arrays, but should be interpreted to also cover e.g. 5×7 or 9×7 Bessel arrays or what have you.

Transducers need not be coupled to a common enclosure in order to function as a Bessel array. Indeed, low frequency performance will in many cases be improved if various ones of the transducers occupy separate enclosure volume(s) than other transducers. For example, it may generally not be ideal to have two “+1” transducers sharing an enclosure volume with a “−1” transducer, nor even with a “+½” transducer.

Although the various embodiments of the invention have been described with reference to implementations in which a single amplifier provides a signal to the Bessel circuit, the invention may just as readily be practiced in implementations in which various ones of the transducer signal paths are driven by separate amplifiers.

Although the invention has been described with reference to loudspeakers in which the multiple transducers are coupled to a single enclosure, the invention can just as easily be practiced in e.g. a modular speaker cabinet system in which subsets of the transducers are coupled to different enclosures. These multiple enclosures may then be stacked, rail mounted, or otherwise affixed such that the transducers are in the correct spacing and alignment.

For simplicity and consistency, the invention has been described with respect to vertically oriented arrays of transducers, but may also be practiced with any other array orientation.

When one component is said to be “adjacent” another component, it should not be interpreted to mean that there is absolutely nothing between the two components, only that they are in the order indicated. The various features illustrated in the figures may be combined in many ways, and should not be interpreted as though limited to the specific embodiments in which they were explained and shown. Those skilled in the art having the benefit of this disclosure will appreciate that many other variations from the foregoing description and drawings may be made within the scope of the present invention. Indeed, the invention is not limited to the details described above. Rather, it is the following claims including any amendments thereto that define the scope of the invention.

What is claimed is:

1. An improvement in a Bessel Array having a transducer array including a plurality of electromagnetic transducers on substantially regular on-center spacing, and an Improved Bessel Circuit coupled to provide signals to the respective transducers, wherein the improvement comprises:
in a position in which, in a conventional Bessel array, there is a non-positive phase signal, the Improved Bessel Circuit providing a positive phase signal to a transducer at that position in a low frequency range, and the Improved Bessel Circuit providing the non-positive phase signal to the transducer at that position in a high frequency range.

2. The improvement of claim 1 wherein:
the non-positive phase signal is a negative phase signal.

3. The improvement of claim 1 wherein:
the non-positive phase signal is a zero signal.

4. An improvement in a Bessel Array having a transducer array including, on substantially regular on-center spacing, a plurality of electromagnetic transducers and at least one no-transducer location, and an Improved Bessel Circuit coupled to provide signals to the respective transducers, wherein the improvement comprises:
an extra transducer disposed within the transducer array at the no-transducer location; and
the Improved Bessel Circuit coupled to provide to the extra transducer a positive signal in a low frequency range and a substantially zero signal in a high frequency range;
whereby low frequency output of the Bessel Array is increased and off-axis Bessel performance is maintained.

5. An improvement in a Bessel Array having a transducer array including, on substantially regular on-center spacing, a plurality of transducers and at least one no-transducer location, and an Improved Bessel Circuit coupled to provide signals to the respective transducers, wherein the improvement comprises:
a first subset of the transducers being offset from a center line of the Bessel Array less than a diameter of one of the transducers.

6. The improvement of claim 5 wherein:
the first subset of the transducers is offset less than a radius of one of the transducers.

7. A Reduced Bessel Array comprising:
exactly four transducers, wherein
a first transducer is coupled to receive a positive phase less than full amplitude signal,
a second transducer is coupled to receive a negative phase substantially full amplitude signal,
a third transducer is coupled to receive a positive phase substantially full amplitude signal, and
a fourth transducer is coupled to receive a positive phase substantially full amplitude signal.

8. An improvement in a Bessel Array including, on substantially regular on-center spacing, a plurality of electromagnetic transducers coupled to be driven by an amplifier, the improvement comprising:
each of the transducers having a dual voice coil structure including a first plurality of voice coil windings and a second plurality of voice coil windings;
for each transducer at a full amplitude Bessel position, both pluralities of voice coil windings being coupled to be driven by the amplifier; and
for each transducer at a half amplitude Bessel position, only one of the pluralities of voice coil windings being coupled to be driven by the amplifier.
